(19) United States
(12) Patent Application Publication
(10) Pub. No.: US 2008/0130345 A1
(43) Pub. Date: Jun. 5, 2008

(54) SEMICONDUCTOR MEMORY DEVICE

(75) Inventor: Wataru ABE, Osaka (JP)

Correspondence Address: DICKINSON WRIGHT PLLC, 1901 L STREET NW, SUITE 800, WASHINGTON, DC, 20036, US

(73) Assignee: MATSUSHITA ELECTRIC INDUSTRIAL CO., LTD., OSAKA (JP)

(21) Appl. No.: 11/941,569

(22) Filed: Nov. 16, 2007

(30) Foreign Application Priority Data
Nov. 16, 2006 (JP) 2006-310556

(51) Int. Cl. G11C 11/4197; G11C 7/12; G11C 7/08

(52) U.S. Cl. 365/104; 365/203; 365/208

(57) ABSTRACT

A semiconductor memory device comprising multiple memory cells, main bit lines, a sub-bit line, a differential amplifier circuit, a precharge circuit, a first control circuit generating first and second control signals, and a second control circuit generating third and fourth control signals, wherein the differential amplifier circuit amplifies the voltage difference between the sub-bit line and the main bit line according to the first and second control signals; the precharge circuit charges the sub-bit line and the main bit line to a first voltage when the third and fourth control signals are activated and charges only the sub-bit line when the third and fourth control signals are inactivated, whereby the voltage of the main bit line is set so as to be lower than the voltage of the sub-bit line, and both the stabilization of reading operation and the increase in capacity are attained.

### BACKGROUND OF THE INVENTION

1. Field of the Invention

The present invention relates to a semiconductor memory device, more particularly, to a memory cell array configuration having a large capacity and being capable of high speed operation without being affected by the increase in the cut-off leak of MOS transistors owing to microfabrication.

2. PRIOR ART

Conventional semiconductor memory devices are disclosed in, for example, Japanese Patent Application Laid-Open Publication No. 6-176592. Paragraphs 0002 to 0006 on page 2 and FIG. 2 of Japanese Patent Application Laid-Open Publication No. 6-176592 disclose the configuration of a mask ROM that stores data depending on the presence or absence of contact connection.

FIG. 19 is a block diagram of a conventional mask ROM. In FIG. 19, numeral 48 designates a memory cell array.

Numeral 2 designates a word line group WLk<i> (k=0 to y, i=0 to n).

Numeral 3 designates a main bit line group MBL<j> (j=0 to m).

Numeral 50 designates a row block selection signal group RBk (k=0 to y).

Numeral 49 designates multiple sub-arrays MSA<i, j> (i=0 to n, j=0 to m).

The memory array 48 comprises multiple sub-arrays 49 MSA<i, j>. In the memory array 48, in the row direction (in other words, the direction in which the values of i are the same), a word line group 2 WLk<i> and a row block selection signal group 50 RBk having a common k value are connected, and in the sub-arrays 49 MSA<i, j> arranged in the column direction (in other words, the direction in which the values of j are the same), a main bit line group 3 MBL<j> having a common j value is connected.

Numeral 5 designates an input buffer. This input buffer 5 shapes the waveforms of address and control signals input from the outside of the mask ROM and transmits the signals to the inside of the mask ROM.

Numeral 6 designates a first decode circuit. This first decode circuit 6 selects one line of the row block selection signal group 50 RBk and one line of the word line group 2 WLk<i> having the same k value depending on a row address selection signal 5a output from the input buffer 5.

Numeral 7 designates a second decode circuit. This second decode circuit 7 selects one line of the main bit line group 3 MBL<j> depending on a column address selection signal 5b output from the input buffer 5.

Numeral 51 designates a sense amplifier. This sense amplifier 51 is connected to the main bit line group 3 MBL<j> via the second decode circuit 7.

Numeral 9 designates a data output buffer. This data output buffer 9 transmits data read and amplified using the sense amplifier 51 to the outside of the mask ROM.

Numeral 52 designates a precharge circuit. This precharge circuit 52 precharges only one main bit line selected from the main bit line group 3 MBL<j> using the second decode circuit 7.

Numeral 53 designates a leak current replenishing circuit. This leak current replenishing circuit 53 replenishes the charge lost owing to cut-off leak current in the main bit line group 3 MBL<j>.

Next, the operation of FIG. 19 will be described referring to FIGS. 20 and 21.

FIG. 20 is a schematic view showing one of the sub-arrays MSA<i, j> of the conventional mask ROM, herein showing a sub-array MSA<0, 0>. FIG. 21 is a schematic view showing the operation waveforms thereof.

In FIG. 20, numeral 54 designates a memory cell group MC<i> (i=0 to n) formed of an N-channel MOS transistor.

Numeral 55 designates a sub-bit line SBL.

Numeral 56 designates a main bit line MBL0. This main bit line 56 MBL0 is one line of the main bit line group 3 MBL<j>.

Numeral 57 designates a word line group WL0<i>. This word line group 57 WL0<i> represents word lines of the word line group 2 WLk<i> which have the same k value.

Numeral 58 designates a row block selection signal. This row block selection signal 58 is one line of the row block selection signal group 50 RBk (k=0 to n).

Letter TG designates a transfer gate formed of an N-channel MOS transistor. This transfer gate TG is inserted between the sub-bit line 55 SBL and the main bit line 56 MBL0, and the row block selection signal 58 RB0 is connected to the gate electrode thereof.

The word line group 57 WL0<i> (i=0 to n) is connected to the gate electrodes of the memory cell group 54 MC<i>, and a ground voltage Vss is connected to the source electrodes thereof. When the drain electrodes of the memory cell group 54 MC<i> are connected to the sub-bit line 55 SBL via contact elements, “0” data is stored (in the memory cell MC<0> in FIG. 20); when not connected, “1” data is stored (in the memory cell MC<n> in FIG. 20). Data to be stored is programmed in a semiconductor manufacturing process.

In the semiconductor memory device configured as described above, its operation will be described using the timing operation waveforms (T00 to T07) shown in FIG. 21. The period from time T00 to time T03 represents a “0” data reading period, and the period from time T04 to time T07 represents a “1” data reading period.

The period before time T00 and the period from time T03 to time T04: initial state

All the row address signals and column address signals are inactive. Hence, the row block selection signal 58 RB0=“L” level, the word line 57 WL0<0>=“L” level, the word line 57 WL0<n>=“L” level, and the main bit line 56 MBL0=“L” level. The sub-bit line 55 SBL is not connected to any power source, thereby being in a floating state (high impedance state); however, since the sub-bit line 55 SBL is not directly connected to the gate electrodes of any MOS transistors, problems, such as unstable transistor operation, do not occur.

Time T00 and time T04: main bit line selection

A column address signal is activated, the main bit line 56 MBL0 is selected, and current supply from the precharge circuit 52 to the main bit line 56 MBL0 starts. Since the transfer gate TG formed of an N-channel MOS transistor is non-conductive at this time, the voltage of the main bit line 56 MBL0 is charged to “H” level.

Time T01 and time T05: low block selection signal selection

The row address signal is activated, and the voltage of the row block selection signal 58 RB0 changes from “L” level to “H” level. As a result, the transfer gate TG formed of an N-channel MOS transistor becomes conductive, and the main bit line 56 MBL0 is electrically connected to the sub-bit line 55 SBL.

Hence, the voltage of the sub-bit line 55 SBL is charged to “H” level (approximately Vdd—the threshold voltage of the transfer gate TG formed of an N-channel MOS transistor) via the main bit line 56 MBL0 and the transfer gate TG formed of an N-channel MOS transistor.

Time T02: word line selection (“0” data reading time)

After the row block selection signal 58 RB0 is activated, the word line 57 WL<0> is selected (=changing from “L” level to “H” level) with an arbitrary time difference (approximately a time during which the voltage of the sub-bit line 55 SBL is charged sufficiently to “H” level), and the memory cell 54 MC<0> becomes conductive. Since the drain electrode of the memory cell 54 MC<0> is connected to the sub-bit line 55 SBL via a contact element at the “0” data reading time, the sub-bit line 55 SBL is electrically connected to the ground voltage Vss via the memory cell 54 MC<0>. As a result, the current supplied from the precharge circuit 52 at time T01 flows into the ground voltage Vss via the main bit line 56 MBL0, the sub-bit line 55 SBL and the memory cell 54 MC<0>, whereby the voltages of the sub-bit line 55 and the main bit line 56 MBL0 change from “H” level to “L” level. This change in the voltage of the main bit line 56 MBL0 from “H” level to “L” level is transferred to the sense amplifier 51 that is connected via the second decode circuit 7, amplified and then read as “0” data from the data output buffer 9 to the outside of the mask ROM.

Time T06: word line selection (“1” data reading time)

After the row block selection signal 58 RB0 is activated, the word line 57 WL<n> is selected (=changing from “L” level to “H” level) with a time difference (approximately a time during which the voltage of the sub-bit line 55 SBL is charged sufficiently to “H” level), and the memory cell 54 MC<n> becomes conductive. However, since the drain electrode of the memory cell 54 MC<n> is not connected to the sub-bit line 55 SBL via a contact element at the “1” data reading time, the sub-bit line 55 SBL is not connected to the ground voltage Vss. As a result, the current supplied from the precharge circuit 52 at time T05 remains stored in the capacity of the main bit line 56 MBL0 the sub-bit line 55 SBL, whereby the voltages of the main bit line 56 MBL0 and the sub-bit line 55 SBL maintain “H” level. This “H” level voltage of the main bit line 56 MBL0 is transferred to the sense amplifier 51 that is connected via the second decode circuit 7, amplified and then read as “1” data from the data output buffer 9 to the outside of the outside of the mask ROM.

Times T03 and T07: reading operation completion

All the row address signals and column address signals are returned to an unselected state so as to be ready for reading operation in the next cycle. Hence, the voltage of the selected row block selection signal 58 RB0 changes from “H” level to “L” level, the voltages of the word line 57 WL0<0> and the word line 57 WL0<n> change from “H” level to “L” level, and the voltage of the main bit line 56 MBL0 becomes “L” level.

According to the conventional example described above, the memory cells can be divided on a sub-array unit basis and connected, without directly connecting all the memory cells to a single bit line. Hence, it is possible to prevent the lowering of the sub-bit line level owing to “cut-off leak current” that occurs in a memory cell group in which the word lines connected to the gate electrode are unselected and the drain electrodes are connected to the bit lines via contact elements; therefore, even if process miniaturization advances and “cut-off leak current” increases, a large-scale memory array can be created. At the same time, it can be expected to have an effect of raising memory access speed by dividing bit lines on a sub-array unit basis.

In the conventional example, since the transfer gate TG formed of an N-channel MOS transistor is inserted between the main bit line 56 MBL0 and the sub-bit line 55 SBL, the conventional example has a defect that “0” data reading is slow in comparison with a mask ROM having a general NOR structure. This is because, in addition to the memory cell MC<0>, the transfer gate TG formed of an N-channel MOS transistor is connected in series with the current pathway between the main bit line 56 and the ground voltage Vss.

Furthermore, as process miniaturization advances, the gate width of the memory cell transistor becomes narrower, and the current drive capability thereof tends to lower; as a result, speeding up obtained by bit line division is hindered, and “0” data reading is delayed further.

The above-mentioned problem has become an important problem to be solved so that semiconductor memory devices satisfy the requirements for “large capacity” and “high speed operation” in digital home electric appliances and the like.

A “differential amplifier circuit” is generally used in a DRAM and the like as means for amplifying a minute amount of current; however, it is difficult to have “a pair bit line structure (a structure in which the voltage of the bit line adjacent to the selected bit line is used as the reference voltage of the differential amplifier circuit)” using adjacent bit lines because of the memory array structure of a mask ROM. Furthermore, unlike the case of the DRAM, no “+ direction reading voltage difference” is generated when the data stored in a memory cell is “1”. In other words, when “1” is stored, the drain terminal of the memory cell of the mask ROM is disconnected from the bit line according to a mask program, and the voltage of the bit line is maintained at the voltage (=the power supply voltage Vdd) charged at the start time of an access cycle. In other words, the voltage of the bit line may become equal to the reference voltage, and normal operation is not carried out if this state remains unchanged. It is thus necessary that the reference voltage should be set so as to be “lower” than the “1” reading voltage. In the case of the DRAM, when a memory cell storing “1” is accessed, the voltage of the bit line becomes “high (several hundred millivolts).”

Although it may be possible to use a method in which a dedicated dummy bit line is provided to supply the reference voltage of the differential amplifier circuit, a differential amplifier circuit is required to be inserted for each bit line to solve the problem that the memory cell current decreases. If the dedicated dummy bit line is simply added to each bit line, area penalty increases. Still further, even if the dedicated dummy bit line can be provided, the number of memory cells, the drain terminals of which are connected to the bit lines, changes variously depending on the user; as a result, “1” reading voltage varies, and setting the reference voltage (the voltage of the dummy bit line) to “low” as described above is very difficult.

Although it may also be possible to use a method in which an independent reference voltage generating circuit is provided separately, the difficulty in the setting remains unchanged. At the same time, the area penalty occurs.

An example in which differential amplifier circuits are used in a mask ROM having a hierarchic structure is disclosed (refer to Japanese Patent Application Laid-Open Publication No. 2001-167591). However, this uses a system in which the voltage of a dummy bit line is used as a reference voltage and the potential difference from the voltage of a selected main bit line is amplified, but does not solve the above-mentioned problems of “the insertion of the transfer gate TG formed of an N-channel MOS transistor” and “the lowering of the current capability of the memory cell transistor owing to miniaturization.”

### SUMMARY OF THE INVENTION

Accordingly, the present invention is intended to provide a semiconductor memory device capable of reading data at high speed even when memory cell current decreases while both the stabilization of reading operation and the increase in capacity are attained.

A first semiconductor memory device according to the present invention comprises:

a first memory cell array in which first sub-arrays provided with multiple first memory cells; a sub-bit line; a differential amplifier circuit having first, second, third and fourth input terminals; and a first precharge circuit having fifth, sixth, seventh and eighth input terminals are disposed in a matrix state,

multiple word lines connected to the first sub-arrays,

multiple main bit lines connected to the first sub-arrays, and

a second precharge circuit for charging the multiple main bit lines, wherein

the differential amplifier circuit, the first and second input terminals of which are connected to the sub-bit line and one of the multiple main bit lines, respectively, and the third and fourth input terminals of which are connected to first and second control signals, respectively, amplifies the difference between the voltage of the sub-bit line and the voltage of the main bit line when the first and second control signals are activated, and

the first precharge circuit, the fifth and sixth input terminals of which are connected to the sub-bit line and one of the multiple main bit lines, respectively, and the seventh and eighth input terminals of which are connected to third and fourth control signals, charges the sub-bit line and the main bit line to a first voltage when the third and fourth control signals are activated, and charges the sub-bit line to a second voltage when the third and fourth control signals are inactivated.

In the semiconductor memory device configured as described above, a hierarchic bit line structure is adopted, the differential amplifier circuit is inserted between the main bit line and the sub-bit line, and the voltage of the main bit is set so as to be lower than the voltage of the sub-bit; hence, both the stability of reading operation and the increase in capacity can be achieved, and it is possible to create a large capacity mask ROM capable of reading data at high speed even when memory cell current decreases.

In the first semiconductor memory device according to the present invention described above, it is preferable that the first memory cell is formed of an N-channel MOS transistor, the gate electrode of which is connected to one of the multiple word lines, the source electrode of which is connected to a ground voltage Vss, and the drain electrode of which is programmably connected to the sub-bit line according to data to be stored.

In addition, in the first semiconductor memory device according to the present invention described above, it is preferable that

the first precharge circuit comprises first and second switching means inserted between the fifth input terminal and the sixth input terminal so as to be connected in parallel with each other, third switching means inserted between a power supply voltage Vdd and the fifth input terminal, and fourth switching means inserted between the power supply voltage Vdd and the sixth input terminal,

the first switching means is formed of an N-channel MOS transistor, the gate electrode of which is connected to the seventh input terminal,

the second switching means is formed of a P-channel MOS transistor, the gate electrode of which is connected to the eighth input terminal,

the third switching means is formed of a P-channel MOS transistor, the gate electrode of which is connected to the seventh input terminal,

the fourth switching means is formed of an N-channel MOS transistor, the gate electrode of which is connected to the seventh input terminal,

when the third control signal connected to the seventh input terminal is activate (“H” level) and the fourth control signal connected to the eighth input terminal is also active (“L” level), the first, second and fourth switching means become conductive, and the third switching means become nonconductive, whereby the sub-bit line connected to the fifth input terminal and the main bit line connected to the sixth input terminal are connected to the power supply voltage Vdd via the fourth switching means, thereby charging the sub-bit line to the first voltage, and

when the third control signal connected to the seventh input terminal is inactivate (“L” level) and the fourth control signal connected to the eighth input terminal is also inactive (“H” level), the first, second and fourth switching means become nonconductive, and the third switching means become conductive, whereby the sub-bit line is connected to the power supply voltage Vdd via the third switching means, thereby charging the sub-bit line to the second voltage.

Furthermore, in the first semiconductor memory device according to the present invention described above, it is preferable that the first voltage is equal to or lower than “the power supply voltage Vdd—the threshold voltage of the fourth switching means” although the first voltage is determined by the current drive capability of the fourth switching means and the cutoff currents of the multiple first memory cells connected to the sub-bit line.

Moreover, in the first semiconductor memory device according to the present invention described above, it is preferable that the second voltage is judged to be H” level in the differential amplifier circuit while the first voltage is used as a reference voltage although the second voltage is determined by the current drive capability of the third switching means and the cutoff currents of the multiple first memory cells connected to the sub-bit line.

Besides, in the first semiconductor memory device according to the present invention described above, it is preferable that

the first and second control signals are activated after the word line is activated,

the third and fourth control signals are pulse signals that are activated in synchronization with an external clock and inactivated after the main bit line and the sub-bit line are charged to the first voltage, and

the word line is activated after the third and fourth control signals are inactivated and after the sub-bit line is charged to the second voltage.

In addition, in the first semiconductor memory device according to the present invention described above, it is preferable that the second precharge circuit charges the main bit line being inactive to “L” level.

Furthermore, in the first semiconductor memory device according to the present invention described above, it is preferable that the current drive capability of the third switching means is smaller than the current drive capability of the first memory cell and has a gate width and a gate length larger than those of the cutoff current of the first memory cell.

Moreover, in the first semiconductor memory device according to the present invention described above, it is preferable that the current drive capability of the fourth switching means has a gate width and a gate length in which the second voltage is judged to be “H” level in the differential amplifier circuit while the first voltage is used as a reference voltage.

Besides, in the first semiconductor memory device according to the present invention described above, it is preferable that the total amount of the cutoff currents of the first memory cells connected to the sub-bit line is smaller than the current drive capability of the third switching means.

A second semiconductor memory device according to the present invention comprises:

a second memory cell array in which second sub-arrays provided with multiple second memory cells; a sub-bit line; a differential amplifier circuit having first, second, third and fourth input terminals; and a first precharge circuit having fifth, sixth, seventh and eighth input terminals are disposed in a matrix state,

multiple word lines connected to the second sub-arrays,

multiple main bit lines connected to the second sub-arrays, and

a second precharge circuit for charging the multiple main bit lines, wherein

the differential amplifier circuit, the first and second input terminals of which are connected to the sub-bit line and one of the multiple main bit lines, respectively, and the third and fourth input terminals of which are connected to first and second control signals, respectively, amplifies the difference between the voltage of the sub-bit line and the voltage of the main bit line when the first and second control signals are activated,

the first precharge circuit, the fifth and sixth input terminals of which are connected to the sub-bit line and one of the multiple main bit lines, respectively, and the seventh and eighth input terminals of which are connected to third and fourth control signals, charges the sub-bit line and the main bit line to a third voltage when the third and fourth control signals are activated, and charges only the sub-bit line to a fourth voltage when the third and fourth control signals are inactivated.

It is undeniable that the semiconductor memory device configured as described above is large in circuit size and complicated in control in comparison with the first embodiment of the present invention; however, since the cutoff current generated in the memory cell can be restricted, power consumption is low, and a mask ROM having larger memory capacity and being capable of reading data at high speed can be created.

In addition, in the second semiconductor memory device according to the present invention described above, it is preferable that the second memory cell is formed of an N-channel MOS transistor, the gate electrode of which is connected to one of the multiple word lines, the source electrode of which is connected to a fifth control signal group, and the drain electrode of which is programmably connected to the sub-bit line according to data to be stored.

Furthermore, in the second semiconductor memory device according to the present invention described above, it is preferable that the fifth control signal becomes active (=ground voltage Vss) when one cell of the second memory cell group is accessed by the source electrodes of the second memory cell group disposed in the same row as one of the multiple word lines, and becomes inactive (=fifth voltage) when no cells of the second memory cell group are accessed, whereby the fifth voltage raises the threshold voltage of the second memory cell and suppresses the generation of cutoff current.

In addition, in the second semiconductor memory device according to the present invention described above, it is preferable that

the first precharge circuit comprises first and second switching means inserted between the fifth input terminal and the sixth input terminal so as to be connected in parallel with each other, third switching means inserted between a power supply voltage Vdd and the fifth input terminal, and fourth switching means inserted between the power supply voltage Vdd and the sixth input terminal,

the first switching means is formed of an N-channel MOS transistor, the gate electrode of which is connected to the seventh input terminal,

the second switching means is formed of a P-channel MOS transistor, the gate electrode of which is connected to the eighth input terminal,

the third switching means is formed of a P-channel MOS transistor, the gate electrode of which is connected to the seventh input terminal,

the fourth switching means is formed of an N-channel MOS transistor, the gate electrode of which is connected to the seventh input terminal,

when the third control signal connected to the seventh input terminal is activate (“H” level) and the fourth control signal connected to the eighth input terminal is also active (“L” level), the first, second and fourth switching means become conductive, and the third switching means becomes nonconductive, whereby the sub-bit line connected to the fifth input terminal and the main bit line connected to the sixth input terminal are connected to the power supply voltage Vdd via the fourth switching means, thereby charging the sub-bit line to the third voltage, and

when the third control signal connected to the seventh input terminal is inactivate (“L” level) and the fourth control signal connected to the eighth input terminal is also inactive (“H” level), the first, second and fourth switching means become nonconductive, and the third switching means becomes conductive, whereby the sub-bit line is connected to the power supply voltage Vdd via the third switching means, thereby charging the sub-bit line to the fourth voltage.

Furthermore, in the configuration described above, it is preferable that

the third voltage is determined by the current drive capability of the fourth switching means and the total amount of the cutoff currents of the multiple second memory cells connected to the sub-bit line but not selected by the word lines,

the fourth voltage is determined by the current drive capability of the third switching means and the total amount of the cutoff currents of the multiple second memory cells connected to the sub-bit line but not selected by the word lines, and

the third voltage is lower than the fourth voltage by the threshold voltage of the fourth switching means, and the fourth voltage is judged to be “H” level in the differential amplifier circuit while the third voltage is used as a reference voltage.

A third semiconductor memory device according to the present invention comprises:

a third memory cell array in which third sub-arrays provided with multiple third memory cells; a sub-bit line; a differential amplifier circuit having first, second, third and fourth input terminals; and a third precharge circuit having ninth, tenth, 11th and 12th input terminals are disposed in a matrix state,

multiple word lines connected to the third sub-arrays,

multiple main bit lines connected to the third sub-arrays, and

a second precharge circuit for charging the multiple main bit lines, wherein the differential amplifier circuit, the first and second input terminals of which are connected to the sub-bit line and one of the multiple main bit lines, respectively, and the third and fourth input terminals of which are connected to first and second control signals, respectively, amplifies the difference between the voltage of the sub-bit line and the voltage of the main bit line when the first and second control signals are activated, and

the third precharge circuit, the ninth and tenth input terminals of which are connected to the sub-bit line and one of the multiple main bit lines, respectively, and the 11th and 12th input terminals of which are connected to third and fourth control signals, charges the sub-bit line and the main bit line to a sixth voltage when the third and fourth control signals are activated.

The semiconductor memory device configured as described above is large in memory cell size in comparison with the first embodiment of the present invention; however, since additional charging to the sub-bit line is not necessary, current consumption can be reduced, and a mask ROM having larger memory capacity and being capable of reading data at high speed can be created.

In addition, in the third semiconductor memory device according to the present invention, it is preferable that the third memory cell is formed of an N-channel MOS transistor, the gate electrode of which is connected to one of the multiple word lines, the source electrode of which is connected to a ground voltage Vss, and the drain electrode of which is connected to the sub-bit line; or the gate electrode of which is connected to the sub-bit line, and the source electrode and the drain electrode of which are connected to the same one of the multiple word lines.

Furthermore, in the third semiconductor memory device according to the present invention described above, it is preferable that

the third precharge circuit comprises first and second switching means inserted between the ninth input terminal and the tenth input terminal so as to be connected in parallel with each other, and fifth switching means inserted between a power supply voltage Vdd and the tenth input terminal,

the first switching means is formed of an N-channel MOS transistor, the gate electrode of which is connected to the 11th input terminal,

the second switching means is formed of a P-channel MOS transistor, the gate electrode of which is connected to the 12th input terminal,

the fifth switching means is formed of an N-channel MOS transistor, the gate electrode of which is connected to the 11th input terminal,

when the third control signal connected to the 11th input terminal is activate (“H” level) and the fourth control signal connected to the 12th input terminal is also active (“L” level), the first, second and fifth switching means become conductive,

the charge transferred from the power supply voltage Vdd via the fifth switching means is redistributed between the capacity of the main bit line connected to the tenth input terminal and the capacity of the sub-bit line connected to the ninth input terminal, thereby charging the sub-bit line and the main bit line to the sixth voltage, and

when the third control signal connected to the 11th input terminal is inactivate (“L” level) and the fourth control signal connected to the 12th input terminal is also inactive (“H” level), the first and second switching means become nonconductive, whereby the sub-bit line is electrically disconnected from the main bit line.

Moreover, in the third semiconductor memory device according to the present invention described above, it is preferable that

when the gate electrode is connected to the sub-bit line according to stored data and when the word line is connected by short-circuiting the source electrode and the drain electrode in the third memory cell, the voltage of the sub-bit line is raised to a seventh voltage by the redistribution of the charge between the gate capacity and the capacity of the sub-bit line owing to the activation of the word line, and

the seventh voltage is judged to be H” level in the differential amplifier circuit while the sixth voltage is used as a reference voltage.

A fourth semiconductor memory device according to the present invention comprises:

a fourth memory cell array in which fourth sub-arrays provided with multiple first memory cells; a sub-bit line; a differential amplifier circuit having first, second, third and fourth input terminals; and a fourth precharge circuit having 13th, 14th and 15th input terminals are disposed in a matrix state,

multiple word lines connected to the fourth sub-arrays,

multiple main bit lines connected to the fourth sub-arrays, and

a second precharge circuit for charging the multiple main bit lines, wherein

the differential amplifier circuit, the first and second input terminals of which are connected to the sub-bit line and one of the multiple main bit lines, respectively, and the third and fourth input terminals of which are connected to first and second control signals, respectively, amplifies the difference between the voltage of the sub-bit line and the voltage of the main bit line when the first and second control signals are activated, and

the fourth precharge circuit, the 13th and 14th input terminals of which are connected to the sub-bit line and one of the multiple main bit lines, respectively, and the 15th input terminal of which is connected to a sixth control signal, charges the main bit line to an eighth voltage when the sixth control signal is activated.

The semiconductor memory device configured as described above is reduced in the number of elements by two and in the number of signals by one in comparison with the first semiconductor memory device of the present invention; hence, the area is made smaller, and a mask ROM having larger memory capacity and being capable of reading data at high speed can be created.

In the fourth semiconductor memory device according to the present invention described above, it is preferable that the first memory cell is formed of an N-channel MOS transistor, the gate electrode of which is connected to one of the multiple word lines, the source electrode of which is connected to a ground voltage Vss, and the drain electrode of which is programmably connected to the sub-bit line according to data to be stored.

In the fourth semiconductor memory device according to the present invention described above, it is preferable that

the fourth precharge circuit comprises sixth switching means inserted between the 13th input terminal and the 114th input terminal and seventh switching means inserted between the power supply voltage Vdd and the 13th input terminal,

the sixth switching means is formed of an N-channel MOS transistor, the gate electrode of which is connected to the 15th input terminal,

the seventh switching means is formed of a P-channel MOS transistor, the gate electrode of which is connected to the ground voltage Vss,

when the sixth control signal connected to the 15th input terminal is activate (“H” level), the sixth switching means becomes conductive, and the seventh switching means is conductive at all times, thereby charging the voltage of the main bit line to the eighth voltage, and

the eighth voltage is lower than the voltage of the sub-bit line by the threshold voltage of the sixth switching means, and the voltage of the sub-bit line is judged to be “H” level in the differential amplifier circuit while the eighth voltage is used as a reference voltage.

A fifth semiconductor memory device according to the present invention comprises:

a fifth memory cell array in which fifth sub-arrays provided with multiple first memory cells; a sub-bit line; a differential amplifier circuit having first, second, third and fourth input terminals; and a fifth precharge circuit having 16th and 17th input terminals are disposed in a matrix state,

multiple word lines connected to the fifth sub-arrays,

multiple main bit lines connected to the fifth sub-arrays, and

a second precharge circuit for charging the multiple main bit lines, wherein

the differential amplifier circuit, the first and second input terminals of which are connected to the sub-bit line and one of the multiple main bit lines, respectively, and the third and fourth input terminals of which are connected to first and second control signals, respectively, amplifies the difference between the voltage of the sub-bit line and the voltage of the main bit line when the first and second control signals are activated, and

the fifth precharge circuit, the 16th input terminal of which is connected to the sub-bit line, charges the sub-bit line to a ninth voltage, and the fifth precharge circuit, the 17th input terminal of which is connected to the main bit line, charges the main bit line to a tenth voltage.

It is undeniable that the semiconductor memory device configured as described above is increased in current, but reduced in the number of elements by two and in the number of signals by two in comparison with the first embodiment of the present invention; hence, the area is made smaller, and a mask ROM having larger memory capacity and being capable of reading data at high speed can be created.

In the fifth semiconductor memory device according to the present invention described above, it is preferable that the first memory cell is formed of an N-channel MOS transistor, the gate electrode of which is connected to one of the multiple word lines, the source electrode of which is connected to a ground voltage Vss, and the drain electrode of which is programmably connected to the sub-bit line according to data to be stored.

In the fifth semiconductor memory device according to the present invention described above, it is preferable that

the fifth precharge circuit comprises eighth switching means inserted between the 16th input terminal and a power supply voltage Vdd and ninth switching means inserted between the 17th input terminal and the power supply voltage Vdd,

the eighth switching means is formed of a P-channel MOS transistor, the gate electrode of which is connected to the ground voltage Vss,

the ninth switching means is formed of an N-channel MOS transistor, the gate electrode of which is connected to the power supply voltage Vdd, and

since the eighth switching means is conductive at all times, the sub-bit line is charged to the ninth voltage, and since the ninth switching means is also conductive at all times, the main bit line is charged to the tenth voltage, and the tenth voltage becomes lower than the ninth voltage by at least the threshold voltage of the ninth switching means, and the voltage of the sub-bit line is judged to be “H” level in the differential amplifier circuit while the tenth voltage is used as a reference voltage.

A sixth semiconductor memory device according to the present invention comprises:

a sixth memory cell array in which sixth sub-arrays provided with multiple first memory cells; a sub-bit line; a differential amplifier circuit having first, second, third and fourth input terminals; and a sixth precharge circuit having 18th, 19th, 20th and 21st input terminals are disposed in a matrix state,

multiple word lines connected to the sixth sub-arrays,

multiple main bit lines connected to the sixth sub-arrays, and

a seventh precharge circuit having 22nd, 23rd and 24th input terminals, wherein

the differential amplifier circuit, the first and second input terminals of which are connected to the sub-bit line and one of the multiple main bit lines, respectively, and the third and fourth input terminals of which are connected to first and second control signals, respectively, amplifies the difference between the voltage of the sub-bit line and the voltage of the main bit line when the first and second control signals are activated,

the 18th and 19th input terminals of the sixth precharge circuit are connected to the sub-bit line and one of the multiple main bit lines, respectively, and the 20th and 21st input terminals thereof are connected to the third and fourth control signals, respectively,

the 22nd input terminal of the seventh precharge circuit is connected to one of the multiple main bit lines, and the 23rd and 24th input terminal thereof are connected to seventh and eighth control signals, respectively, and

when the third and fourth control signals are activated, the sub-bit line and the main bit line are charged to an 11th voltage; and when the seventh and eighth control signals are activated after the third and fourth control signals are inactivated, only the voltage of the main bit line is charged to a 12th voltage.

It is undeniable that the semiconductor memory device configured as described above is increased in the number of elements and complicated in control in comparison with the first semiconductor memory device according to the present invention, but it is not necessary to set the sub-bit line to “H” level at the time of inactivation, and current consumption is low; hence, a mask ROM having larger memory capacity and being capable of reading data at high speed can be created.

In the sixth semiconductor memory device according to the present invention described above, it is preferable that the first memory cell is formed of an N-channel MOS transistor, the gate electrode of which is connected to one of the multiple word lines, the source electrode of which is connected to a ground voltage Vss, and the drain electrode of which is programmably connected to the sub-bit line according to data to be stored.

In the sixth semiconductor memory device according to the present invention described above, it is preferable that

the sixth precharge circuit comprises tenth and 11th switching means inserted between the 18th input terminal and the 19th input terminal so as to be connected in parallel with each other, 12th switching means inserted between a power supply voltage Vdd and the 18th input terminal, and 13th switching means inserted between the power supply voltage Vdd and the 19th input terminal,

the tenth switching means is formed of an N-channel MOS transistor, the gate electrode of which is connected to the 20th input terminal,

the 11th, 12th and 13th switching means are formed of a P-channel MOS transistor, each gate electrode of which is connected to the 21st input terminal,

the seventh precharge circuit comprises 14th switching means inserted between the 22nd input terminal and the power supply voltage Vdd and 15th switching means inserted between the 22nd input terminal and the ground voltage Vss,

the 14th switching means is formed of a P-channel MOS transistor, the gate electrode of which is connected to the seventh control signal,

the 15th switching means is formed of an N-channel MOS transistor, the gate electrode of which is connected to the eighth control signal,

when the third control signal connected to the 20th input terminal is activate (“H” level), the fourth control signal connected to the 21st input terminal is active (“L” level), the seventh control signal connected to the 23rd input terminal is inactive (“H” level), and the eighth control signal connected to the 24th input terminal is inactive (“L” level), the tenth and 11th switching means become conductive, the 12th and 13th switching means also become conductive, and the 14th and 15th switching means become nonconductive; hence, the sub-bit line and the main bit line are charged to the 11th voltage,

when the third control signal connected to the 20th input terminal is inactivate (“L” level), the fourth control signal connected to the 21st input terminal is inactive (“H” level), the seventh control signal connected to the 23rd input terminal is active (“L” level), and the eighth control signal connected to the 24th input terminal is active (“H” level), the tenth, 11th, 12th and 13th switching means are nonconductive, and the 14th and 15th switching means are conductive, whereby the main bit line is charged to the 12th voltage, and

the 12th voltage is a voltage determined uniquely by the current drive capabilities of the 14th and 15th switching means, and the voltage (=the 11th voltage) of the sub-bit line is judged to be H” level in the differential amplifier circuit while the 12th voltage is used as a reference voltage.

As described above, the present invention is intended to solve conventional problems; since a hierarchic bit line structure is adopted, the differential amplifier circuit is inserted between the main bit line and the sub-bit line, and the voltage of the main bit line is set so as to be lower than the voltage of the sub-bit line, both the stability of reading operation and the increase in capacity are achieved; therefore, the present invention easily provides a semiconductor memory device capable of reading data at high speed even when memory cell current decreases.

### BRIEF DESCRIPTION OF THE DRAWINGS

FIG. 1 is a schematic view showing a semiconductor device according to a first embodiment of the present invention;

FIG. 2 is a schematic view showing a sub-array according to the first embodiment;

FIG. 3 is a schematic view showing operation waveforms according to the first embodiment;

FIG. 4 is a schematic view showing a semiconductor device according to a second embodiment of the present invention;

FIG. 5 is a schematic view showing a sub-array according to the second embodiment;

FIG. 6 is a schematic view showing operation waveforms according to the second embodiment;

FIG. 7 is a schematic view showing a semiconductor device according to a third embodiment of the present invention;

FIG. 8 is a schematic view showing a sub-array according to the third embodiment;

FIG. 9 is a schematic view showing operation waveforms according to the third embodiment;

FIG. 10 is a schematic view showing a semiconductor device according to a fourth embodiment of the present invention;

FIG. 11 is a schematic view showing a sub-array according to the fourth embodiment;

FIG. 12 is a schematic view showing operation waveforms according to the fourth embodiment;

FIG. 13 is a schematic view showing a semiconductor device according to a fifth embodiment of the present invention;

FIG. 14 is a schematic view showing a sub-array according to the fifth embodiment;

FIG. 15 is a schematic view showing operation waveforms according to the fifth embodiment;

FIG. 16 is a schematic view showing a semiconductor device according to a sixth embodiment of the present invention;

FIG. 17 is a schematic view showing a sub-array according to the sixth embodiment;

FIG. 18 is a schematic view showing operation waveforms according to the sixth embodiment;

FIG. 19 is a schematic view showing a semiconductor memory device according to the conventional example;

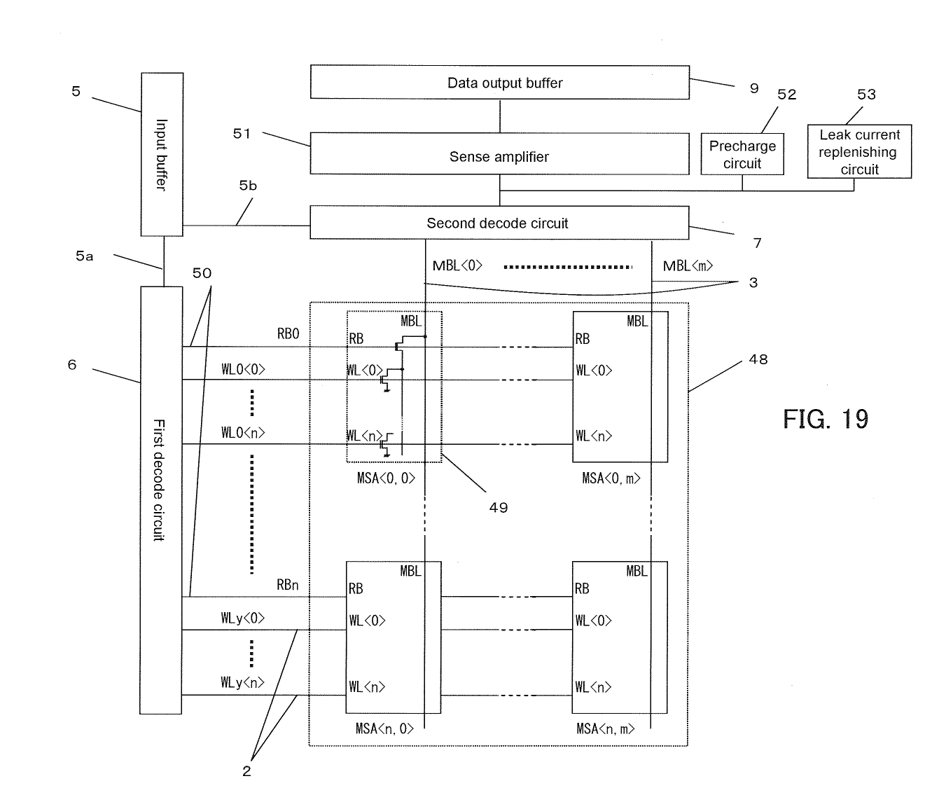

FIG. 20 is a schematic view showing a sub-array according to the conventional example; and

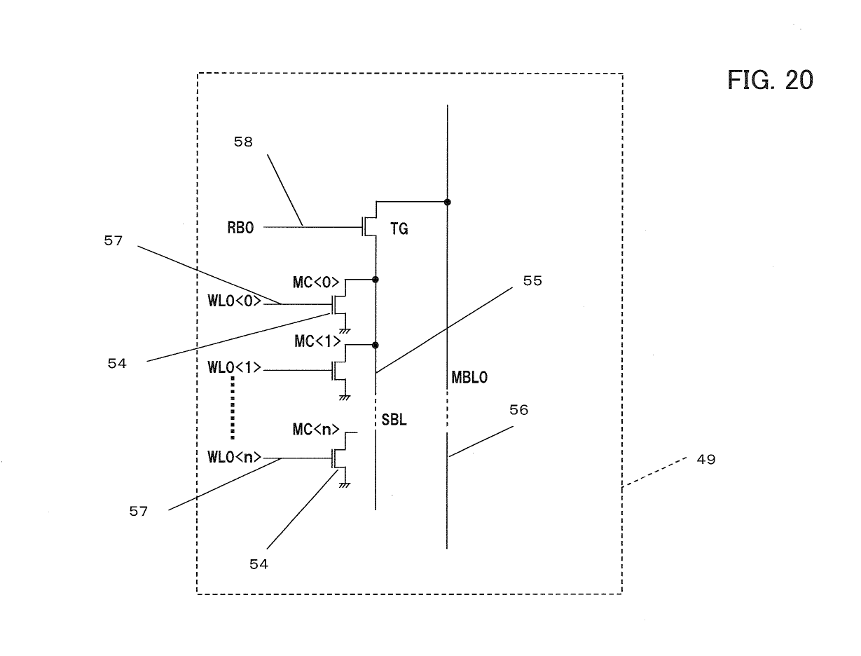

FIG. 21 is a schematic view showing operation waveforms according to the conventional example.

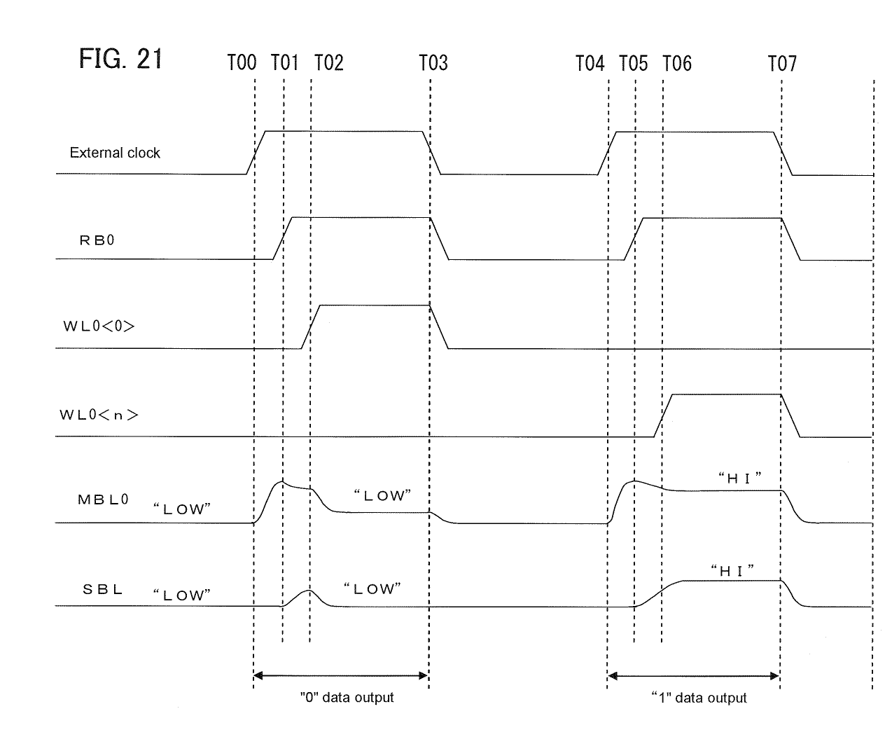

### PREFERRED EMBODIMENTS

Embodiments according to the present invention will be described below in detail referring to the drawings.

### First Embodiment

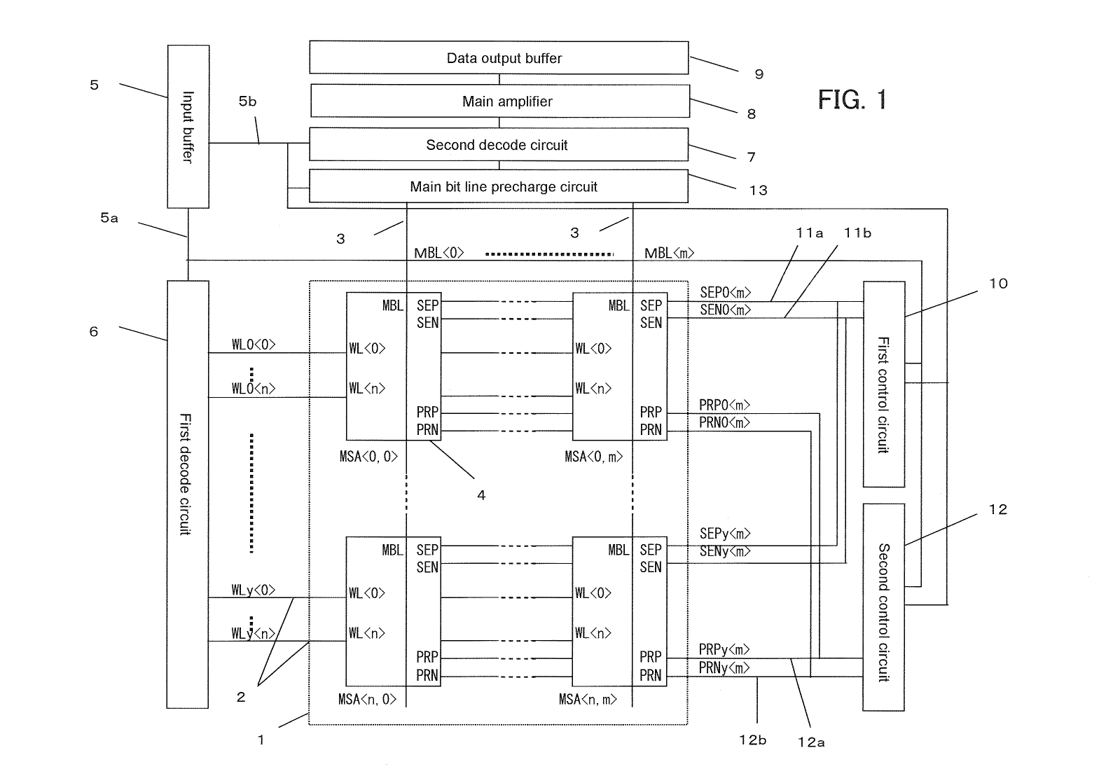

FIG. 1 is a schematic view showing a circuit according to a first embodiment of the present invention.

In FIG. 1, numeral 1 designates a memory cell array. Numeral 2 designates a word line group WLk<i> (k=0 to y, i=0 to n). Numeral 3 designates a main bit line group MBL<j> (j=0 to m) Numeral 4 designates multiple sub-arrays MSA<i, j> (i=0 to n, j=0 to m).

The memory array 1 comprises multiple sub-arrays 4 MSA<i, j>. In the memory array 1, in the sub-arrays 4 MSA<i, j> arranged in the column direction (in other words, the direction in which the values of j are the same), a main bit line group 3 MBL<j> with a common j value is connected.

Numeral 5 designates an input buffer. This input buffer 5 shapes the waveforms of address and control signals input from the outside of the mask ROM and transmits the signals to the inside of the mask ROM.

Numeral 6 designates a first decode circuit. This first decode circuit 6 selects one line of the word line group 2 WLk<i> depending on a row address selection signal 5a output from the input buffer 5.

Numeral 7 designates a second decode circuit. This second decode circuit 7 selects one line of the main bit line group 3 MBL<j> depending on a column address selection signal 5b output from the input buffer 5.

Numeral 8 designates a main amplifier. This main amplifier 8 is connected to the main bit line group 3 MBL<j> via the second decode circuit 7.

Numeral 9 designates a data output buffer. This data output buffer 9 transmits data read and amplified using the main amplifier 8 to the outside of the mask ROM.

Numeral 10 designates a first control circuit.

Numeral 11a designates a sub-amp control signal SEPk<j>. Numeral 11b designates a sub-amp control signal SENk<j>.

The first control circuit 10 generates the sub-amp control signal 11a SEPk<j> and the sub-amp control signal 11b SENk<j> depending on the row address selection signal 5a and the column selection signal 5b.

Numeral 12 designates a second control circuit. Numeral 12a designates a sub-precharge control signal PRPk<j>. Numeral 12b designates a sub-precharge control signal PRNk<j>.

The second control circuit 12 generates the sub-precharge control signal 12a PRPk<j> and the sub-precharge control signal 12b PRNk<j> depending on the row address selection signal 5a and the column address selection signal 5b.

Numeral 13 designates a main bit line precharge circuit. This main bit line precharge circuit 13 charges a main bit line group 3 MBL<j> being unselected to “L” level.

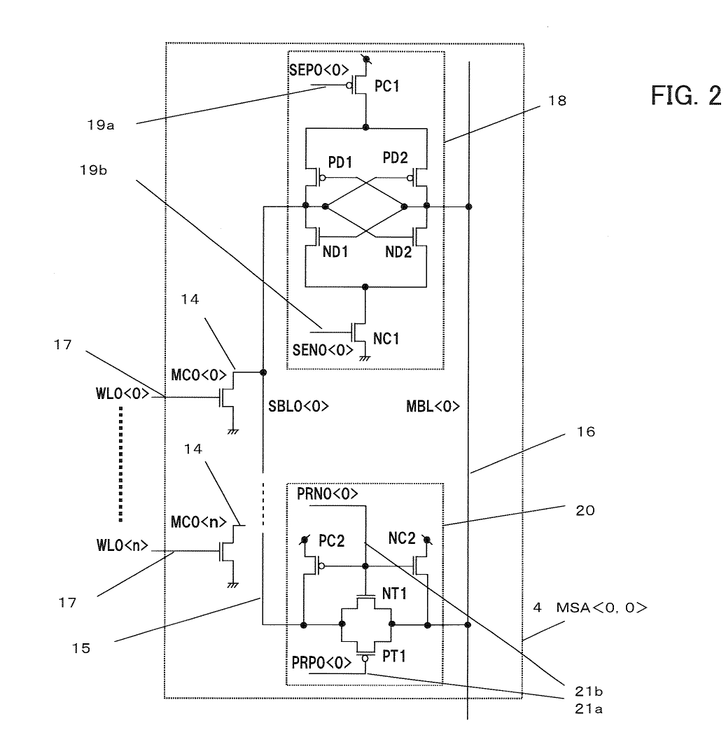

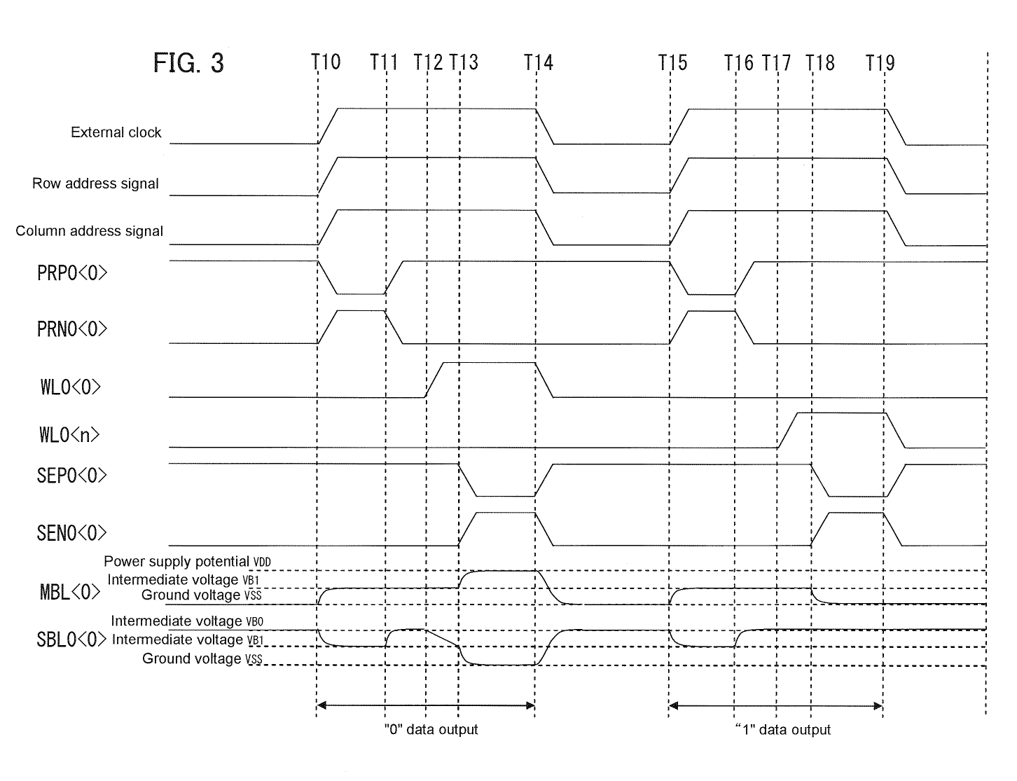

Next, the operation of FIG. 1 will be described referring to FIGS. 2 and 3. FIG. 2 is a schematic view showing the sub-array according to the first embodiment of the present invention, herein showing MSA<0, 0>, one of the sub-arrays 4 MSA<i, j> shown in FIG. 1.

In FIG. 2, numeral 14 designates a memory cell group MC0<i> formed of an N-channel MOS transistor and represents one set (k=0) of the memory cell group MCk<i> (k=0 to y, i=0 to n).

Numeral 15 designates a sub-bit line SBL0<0>. This sub-bit line 15 SBL0<0> represents one of multiple sub-bit lines SBLk<j> (k=0 to y, j=0 to m).

Numeral 16 designates a main bit line MBL<0>. This main bit line 16 MBL<0> represents one line of the main bit line group 3 MBL<j>.

Numeral 17 designates a word line group WL0<i>. This word line group 17 WL0<i> represents one set (k=0) of the word line group 2 WLk<i> (k=0 to y, i=0 to n).

Numeral 18 designates a sub-amp circuit. This sub-amp circuit 18 is a differential amplifier circuit comprising P-channel MOS transistors PC1, PD1 and PD2 and N-channel MOS transistors NC1, ND1 and ND2.

Numeral 19a designates a sub-amp control signal SEP0<0>. This sub-amp control signal 19a SEP0<0> represents one signal of the sub-amp control signal group 11a SEPk<j> (k=0 to y, j=0 to m).

Numeral 19b designates a sub-amp control signal SEN0<0>. This sub-amp control signal 19b SEN0<0> represents one signal of the sub-amp control signal group 11b SENk<j> (k=0 to y, j=0 to m).

Numeral 20 designates a sub-precharge circuit.

Numeral 21a designates a sub-precharge control signal PRP0<0>. This sub-precharge control signal 21a PRP0<0> represents one signal of the sub-precharge control signal group 12a PRPk<j> (k=0 to y, j=0 to m).

Numeral 21b designates a sub-precharge control signal PRN0<0>. This sub-precharge control signal 21b PRN0<0> represents one signal of the sub-precharge control signal group 12b PRNk<j> (k=0 to y, j=0 to m). The sub-precharge circuit 20 comprises a P-channel MOS transistor PT1 inserted between the sub-bit line 15 SBL0<0> and the main bit line 16 MBL<0>, the gate electrode of which is connected to the sub-precharge control signal 21a PRP0<0>; an N-channel MOS transistor NT1 inserted between the sub-bit line 15 SBL0<0> and the main bit line 16 MBL<0>, the gate electrode of which is connected to the sub-precharge control signal 21b PRN0<0>; a P-channel MOS transistor PC2 inserted between the sub-bit line 15 SBL0<0> and the power supply voltage Vdd, the gate electrode of which is connected to the sub-precharge control signal 21b PRN0<0>; and an N-channel MOS transistor NC2 inserted between the main bit line 16 MBL<0> and the power supply voltage Vdd, the gate electrode of which is connected to the sub-precharge control signal 21b PRN0<0>.

The word line group 17 WL0<i> (i=0 to n) is connected to the gate electrodes of the memory cell group 14 MC0<i> (i=0 to n), and a ground voltage Vss is connected to the source electrodes thereof. When the drain electrodes of the memory cell group 14 MC<i> are connected to the sub-bit line 15 SBL0<0> via contact elements, “0” data is stored (in the memory cell MC0<0> in FIG. 2); when not connected, “1” data is stored (in the memory cell MC0<n> in FIG. 2). Data to be stored is programmed in a semiconductor manufacturing process.

In the semiconductor memory device configured as described above, its operation will be described using the timing operation waveforms (T10 to T19) shown in FIG. 3. The period from time T10 to time T14 represents a “0” data reading period, and the period from time T15 to time T19 represents a “1” data reading period.

The period before time T10 and the period from time T14 to time T15: initial state

All the row address signals and column address signals are inactive. Hence, the voltages of the word lines 17 WL0<1> and WL0<n> are “L” level, and the voltage of the main bit line MBL<0> is “L” level. The main bit line group 3 MBL<j> being unselected is precharged to “L” level using the main bit line precharge circuit 13. Since the sub-precharge control signal 21a PRP0<0> is “H” level and the sub-precharge control signal 21b PRN0<0> is “L” level at this time, the P-channel MOS transistor PC2 becomes conductive, and the sub-bit line 15 SBL0<0> has a voltage arbitrarily determined by the cutoff currents generated in the memory cell group 14 MC0<i> connected to the sub-bit line 15 SBL0<0> and the current of the P-channel MOS transistor PC2. This voltage is shown as an intermediate voltage VB0 in FIG. 3. In addition, since the sub-amp control signal 19a SEP0<0> is “H” level and the sub-amp control signal 19b SEN0<0> is “L” level, the sub-amp circuit 18 is in a stopped state.

The period from time T10 to time T11 and the period from time T15 to time T16: main bit line precharging and sub-bit line equalizing periods

One of the row address signals and one of the column address signals are activated, and the main bit line 16 MBL<0> is selected. Hence, the “L” level charging to the main bit line 16 MBL<0> using the main bit line precharge circuit 13 is stopped. The sub-precharge control signal 21a PRP0<0> is a one-shot pulse signal changing from “H”, “L” “H” level, and the sub-precharge control signal 21b PRN0<0> is a one-shot pulse signal changing from “L”→“H”→“L” level; in this period, since the sub-precharge control signal 21a PRP0<0> is “L” level and the sub-precharge control signal 21b PRN0<0> is “H” level, the P-channel MOS transistor PT1, the N-channel MOS transistor NT1 and the N-channel MOS transistor NC2 become conductive, and the P-channel MOS transistor PC2 becomes nonconductive. Hence, the voltages of the sub-bit line 15 SBL0<0> and the main bit line 16 MBL<0> have a value (=the power supply voltage Vdd—the threshold voltage of the N-channel MOS transistor NC2 or less) arbitrarily determined by the cutoff currents generated in the memory cell group 14 MC0<I> connected to the sub-bit line 15 SBL0<0> and the current of the N-channel MOS transistor NC2. This voltage is shown as an intermediate voltage VB1 in FIG. 3.

The period from time T11 to time T12 and the period from time T16 to time T17: sub-bit line additional charging period

Since the sub-precharge control signal 21a PRP0<0> and the sub-precharge control signal 21b PRN0<0> are inactivated at time T11 and time T16, respectively, the P-channel MOS transistor PT1, the N-channel MOS transistor NT1 and the N-channel MOS transistor NC2 become nonconductive, and the P-channel MOS transistor PC2 becomes conductive. As a result, the voltage of the sub-bit line 15 SBL0<0> becomes the intermediate voltage VB0 while the voltage of the main bit line 16 MBL<0> is maintained at the intermediate voltage VB1.

Time T12: word line selection (“0” data reading start)

When the word line 17 WL0<0> is activated at time T12, the voltage of the sub-bit line 15 SBL0<0> is gradually lowered to the ground voltage Vss via the memory cell 14 MC0<0>.

Time T13: sub-amp start (“0” data reading completion)

At time T13, the sub-amp control signal 19a SEP0<0> becomes “L” level, the sub-amp control signal 19b SEN0<0> becomes “H” level, and the sub-amp circuit 18 is started. The sub-amp circuit 18 recognizes that the voltage of the sub-bit line 15 SBL0<0> is “L” level and lowers the voltage to the ground voltage Vss, and recognizes that the voltage of the main bit line 16 MBL<0> is “H” level and raises the voltage to the power supply voltage Vdd by adjusting time T13 so that the voltage of the sub-bit line 15 SBL0<0> becomes sufficiently lower than the voltage VB1 of the main bit line 16 MBL<0>.

The “H” level voltage of the main bit line 16 MBL<0> is output as “0” data to the outside of the mask ROM via the main amp 8 and the data output buffer 9.

Time T17: word line selection (“1” data reading start)

Even when the word line 17 WL0<n> is activated at time T17, the voltage of the sub-bit line 15 SBL0<0> is maintained at the intermediate voltage VB0.

Time T18: sub-amp start (“1” data reading completion)

At time T18, the sub-amp control signal 19a SEP0<0> is activated to “L” level and the sub-amp control signal 19b SEN0<0> is activated to “H” level, and the sub-amp circuit 18 is started. Since the voltage VB1 of the main bit line 16 MBL<0> is lower than the voltage VB0 of the sub-bit line 15 SBL0<0> by the threshold voltage of the N-channel MOS transistor, the sub-amp circuit 18 recognizes that the voltage of the main bit line 16 MBL<0> is “L” level and lowers the voltage to the ground voltage Vss.

The “L” level voltage of the main bit line 16 MBL<0> is output as “1” data to the outside of the mask ROM via the main amp 8 and the data output buffer 9.

Time T14, time T19; end of reading operation

Since the row address signal and the column address signal are inactivated respectively, the “L” level charging to the main bit line 16 MBL<0> is restarted using the main bit line precharge circuit 13. Furthermore, since the sub-amp control signal 19a SEP0<0> and the sub-amp control signal 19b SEN0<0> are inactivated respectively, the sub-bit line 15 SBL0<0> is charged to the intermediate voltage VB0.

As described above, the semiconductor memory device according to the first embodiment of the present invention has a hierarchic structure, and the differential amplifier circuit is inserted between the main bit line and the sub-bit line, and the voltage of the main bit line is set so as to be lower than the voltage of the sub-bit line; hence, both the increase in capacity and the stability of reading operation can be achieved. It is thus possible to create a large capacity mask ROM capable of reading data at high speed even when memory cell current decreases.

Furthermore, since the sub-amp circuit 18 and the sub-precharge circuit 20 are activated respectively for each sub-array 4 MSA<i, j> selected using the row address signal and the column address signal, the effect of power saving is also achieved.

### Second Embodiment

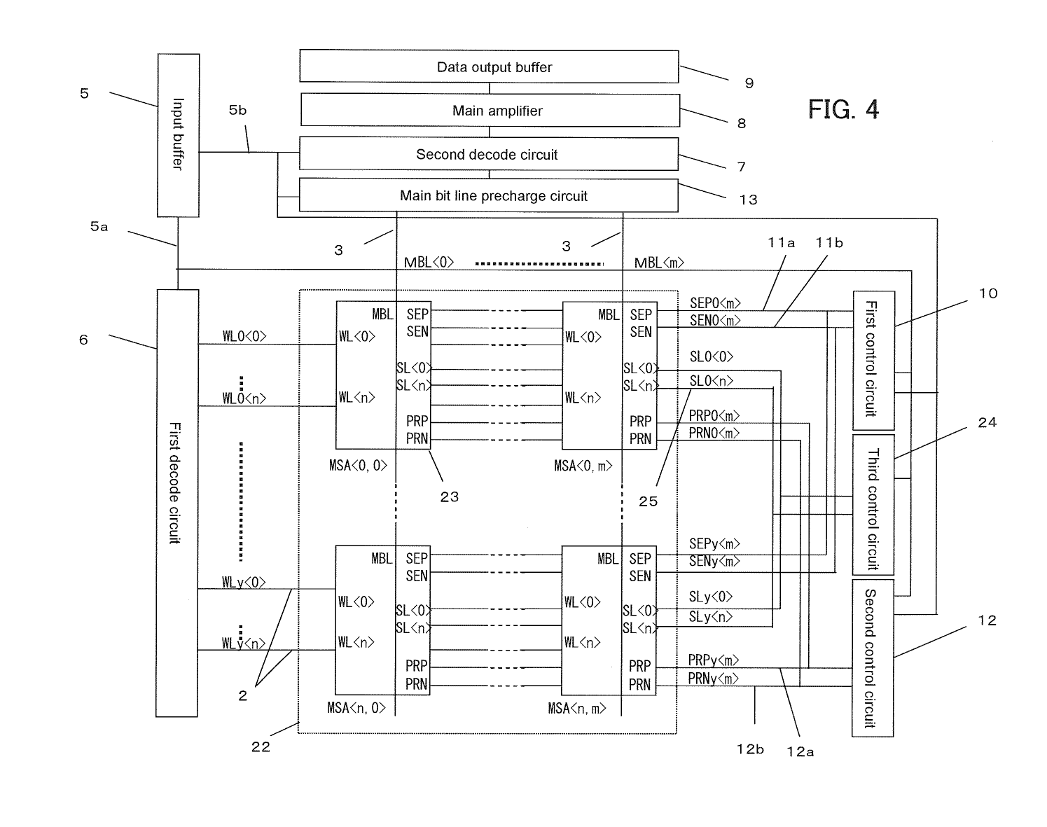

FIG. 4 is a schematic view showing a circuit according to a second embodiment of the present invention.

Since FIG. 4 is different from FIG. 1 showing the first embodiment of the present invention only in that the memory cell array 1 is replaced with a memory cell array 22, that the sub-array 4 is replaced with a sub-array 23, and that a third control circuit 24 and a source control signal group 25 SLk<i> (k=0 to y, i=0 to n) are added, its detailed description is omitted.

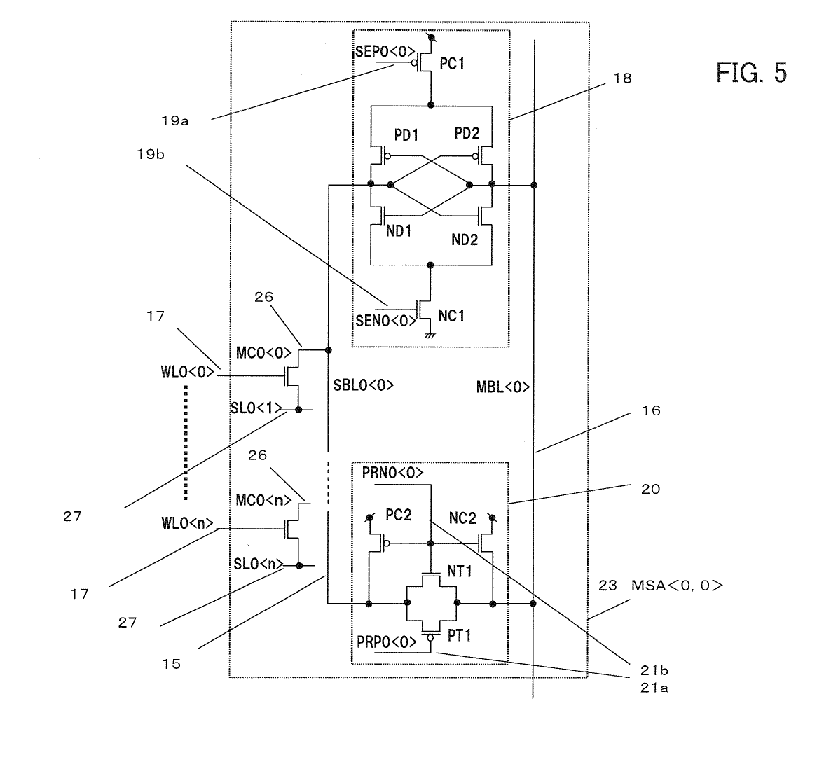

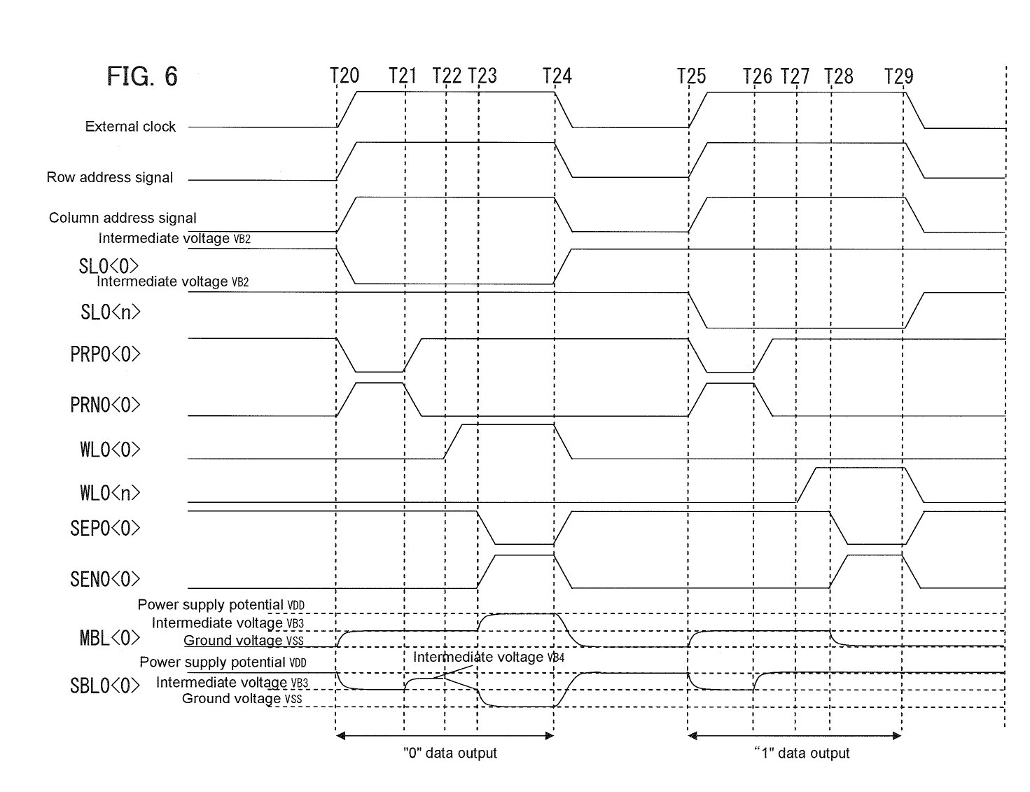

Next, the operation of FIG. 4 will be described referring to FIGS. 5 and 6. FIG. 5 is a schematic view showing the sub-array according to the second embodiment of the present invention and is different from FIG. 2 only in that the memory cell group 14 is replaced with a memory cell group 26 and that source control signals 27 SL0<i> (i=0 to n) are added; hence, its detailed description is omitted. The source control signals 27 SL0<i> are one set (k=0) of the source control signal group 25 SLk<i> (k=0 to y, i=0 to n).

The word line group WL0<i> (i=1 to n) is connected to the gate electrodes of the memory cell group 26 MC0<i> (i=1 to n), and the source control signals 27 SL0<i> (i=0 to n) are connected to the source electrodes. The voltage of the source control signals 27 SL0<i> is changed to the ground voltage Vss when the memory cell group 26 MC0<i> is selected; when not selected, the voltage is changed to a voltage (shown as an intermediate voltage VB2 in FIG. 6) that is set to raise the threshold voltage of the memory cell group 26 MC0<i> and to suppress the generation of cutoff current.

When the drain electrodes of the memory cell group 26 MC<i> are connected to the sub-bit line 15 SBL0<0> via contact elements, “0” data is stored (in the memory cell MC0<0> in FIG. 5); when not connected, “1” data is stored (in the memory cell MC0<n> in FIG. 5). Data to be stored is programmed in a semiconductor manufacturing process.

In the semiconductor memory device configured as described above, its operation will be described using the timing operation waveforms (T20 to T29) shown in FIG. 6. The period from time T20 to time T24 represents a “0” data reading period, and the period from time T25 to time T29 represents a “1” data reading period. FIG. 6 is different from FIG. 3 only in that the source control signals 27 SL0<0> and SL0<n> are added.

The period before time T20 and the period from time T24 to time T25: initial state

All the row address signals and column address signals are inactive. Hence, the voltages of the word lines 17 WL<1> and WL0<n> are “L” level, and the voltage of the main bit line MBL<0> is “L” level. At this time, the main bit line group 3 MBL<0> being unselected is precharged to “L” level using the main bit line precharge circuit 13. At this time, the source control signals 27 SL0<0> and SL0<n> have a voltage (the intermediate voltage VB2) that is set to suppress the cutoff currents of the memory cell group 26 MC<0> and MC<n>. In addition, since the sub-precharge control signal 21a PRP0<0> is “H” level and the sub-precharge control signal 21b PRN0<0> is “L” level, the P-channel MOS transistor PC2 becomes conductive, and the voltage of the sub-bit line 15 SBL0<0> becomes the power supply voltage Vdd. Furthermore, since the sub-amp control signal 19a SEP0<0> is “H” level and the sub-amp control signal 19b SEN0<0> is “L” level, the sub-amp circuit 18 is in a stopped state.

The period from time T20 to time T21 and the period from time T25 to time T26: main bit line precharging and sub-bit line equalizing periods

One of the row address signals and one of the column address signals are activated, and the main bit line 16 MBL<0> is selected. At this time, the “L” level charging to the main bit line 16 MBL<0> using the main bit line precharge circuit 13 is stopped.

The sub-precharge control signal 21a PRP0<0> is a one-shot pulse signal changing from “H”→“L”→“H” level, and the sub-precharge control signal 21b PRN0<0> is a one-shot pulse signal changing from “L”→“H”→“L” level. In this period, since the sub-precharge control signal 21a PRP0<0> is “L” level and the sub-precharge control signal 21b PRN0<0> is “H” level, the P-channel MOS transistor PT1, the N-channel MOS transistor NT1 and the N-channel MOS transistor NC2 become conductive, and the P-channel MOS transistor PC2 becomes nonconductive.

At the same time, since the source control signal 27 (SL0<0> in the period from time T20 to time T21, and SL0<n> in the period from time T25 to time T26) is changed to have the ground voltage Vss, the voltages of the sub-bit line 15 SBL0<0> and the main bit line 16 MBL<0> have a value (=the power supply voltage Vdd—the threshold voltage of the N-channel MOS transistor NC2 or less) arbitrarily determined by the cutoff currents generated in the memory cell group 26 MC0<0> connected to the sub-bit line 15 SBL0<0> and the current of the N-channel MOS transistor NC2 in the period from time T20 to time T21. This voltage is shown as an intermediate voltage VB3 in FIG. 6. In the period from time T25 to time T26, the voltages become the power supply voltage Vdd—the threshold voltage of the N-channel MOS transistor NC2.

In the period from time T25 and time T26, although the source control signal SL0<n> is changed to have the ground voltage, since the drain of the transistor of the memory cell MC<n> is open, the voltage of the sub-bit line is not affected.

The period from time T21 to Time T22 and the period from time T26 to Time T27: sub-bit line additional charging period

At time T21 and time T26, since the sub-precharge control signals 21a PRP0<0> and 21b PRN0<0> are inactivated, the P-channel MOS transistor PT1, the N-channel MOS transistor NT1 and the N-channel MOS transistor NC2 become nonconductive, and the P-channel MOS transistor PC2 becomes conductive.

Hence, while the voltage of the main bit line 16 MBL<0> is maintained at the intermediate voltage VB3, the voltage of the sub-bit line 15 SBL0<0> becomes a voltage (shown as an intermediate voltage VB4 in FIG. 6) that is arbitrarily determined by the current capability of the P-channel MOS transistor PC2 and the cutoff currents generated in the memory cell group 26 MC0<0> in the period from time T21 to time T22. In the period from time T26 to time T27, the voltage becomes the power supply voltage Vdd.

Time T22: word line selection (“0” data reading start)

When the word line 17 WL0<0> is activated at time T22, the voltage of the sub-bit line 15 SBL0<0> is gradually lowered to the ground voltage Vss via the memory cell MC0<0>.

Time T23: sub-amp start (“0” data reading completion)

At time T23, the sub-amp control signal 19a SEP0<0> becomes “L” level, the sub-amp control signal 19b SEN0<0> becomes “H” level, and the sub-amp circuit 18 is started. The sub-amp circuit 18 recognizes that the voltage of the sub-bit line 15 SBL0<0> is “L” level and lowers the voltage to the ground voltage Vss, and recognizes that the voltage of the main bit line 16 MBL<0> is “H” level and raises the voltage to the power supply voltage Vdd by adjusting time T23 so that the voltage of the sub-bit line 15 SBL0<0> becomes sufficiently lower than the voltage VB3 of the main bit line 16 MBL<0>.

The “H” level voltage of the main bit line 16 MBL<0> is output as “0” data to the outside of the mask ROM via the main amp 8 and the data output buffer 9.

Time T27: word line selection (“1” data reading start)

Even when the word line 17 WL0<n> is activated at time T27, the voltage of the sub-bit line 15 SBL0<0> is maintained at the power supply voltage Vdd.

Time T28: sub-amp start (“1” data reading completion)

At time T28, the sub-amp control signal 19a SEP0<0> is activated to “L” level and the sub-amp control signal 19b SEN0<0> is activated to “H” level, and the sub-amp circuit 18 is started. Since the voltage (=the power supply voltage Vdd—the threshold voltage of the N-channel MOS transistor) of the main bit line 16 MBL<0> is lower than the voltage (=the power supply voltage Vdd) of the sub-bit line 15 SBL0<0>, the voltage of the main bit line 16 MBL<0> is lowered to the ground voltage Vss.

The “L” level voltage of the main bit line 16 MBL<0> is output as “1” data to the outside of the mask ROM via the main amp 8 and the data output buffer 9.

Time T24, time T29; end of reading operation

Since the row address signal and the column address signal are inactivated respectively, the “L” level charging to the main bit line 16 MBL<0> is restarted using the main bit line precharge circuit 13. Furthermore, since the source control signal 27 SL0<i> is also changed to have the intermediate voltage VB2, the voltage of the sub-bit line 15 SBL0<0> becomes the power supply voltage Vdd.

It is undeniable that the semiconductor memory device according to the second embodiment of the present invention is large in circuit size and complicated in control in comparison with the first embodiment of the present invention as described above; however, since the cutoff current generated in the memory cell can be restricted, power consumption is low, and a mask ROM having larger memory capacity and being capable of reading data at high speed can be created.

### Third Embodiment

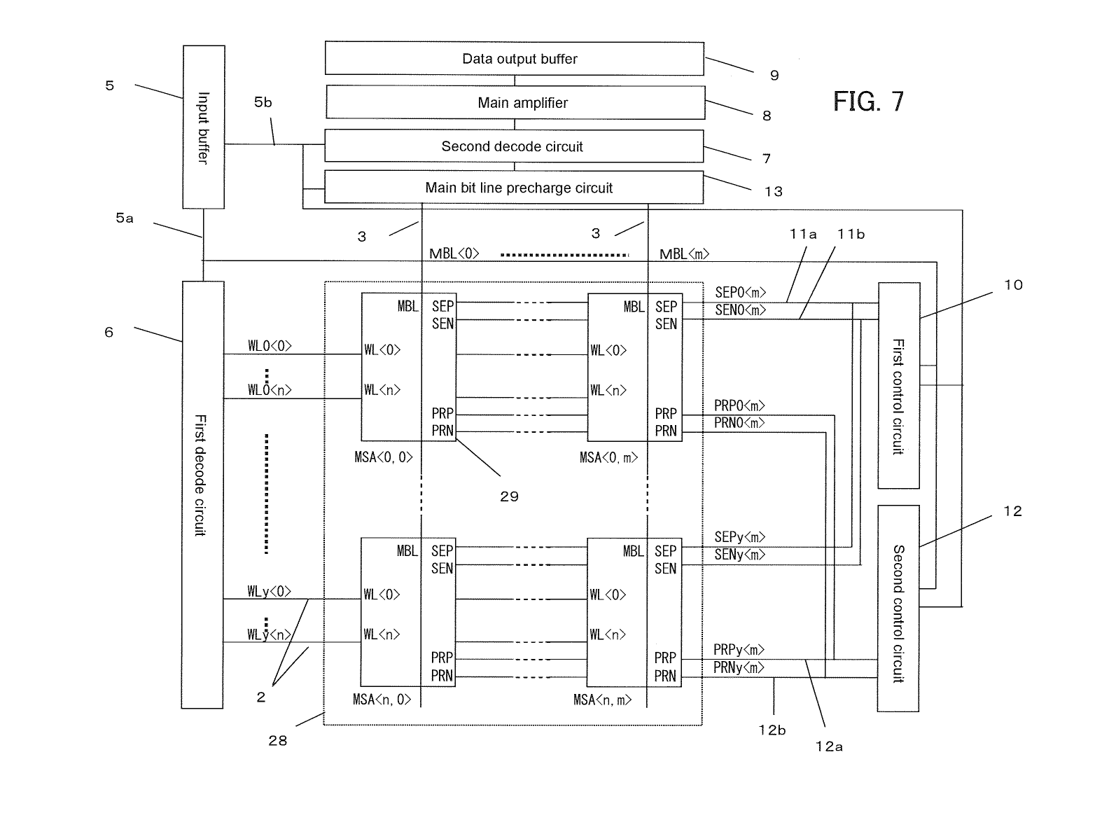

FIG. 7 is a schematic view showing a circuit according to a third embodiment of the present invention.

Since FIG. 7 is different from FIG. 1 showing the first embodiment of the present invention only in that the memory cell array 1 is replaced with a memory cell array 28 and that the sub-array 4 is replaced with a sub-array 29, its detailed description is omitted.

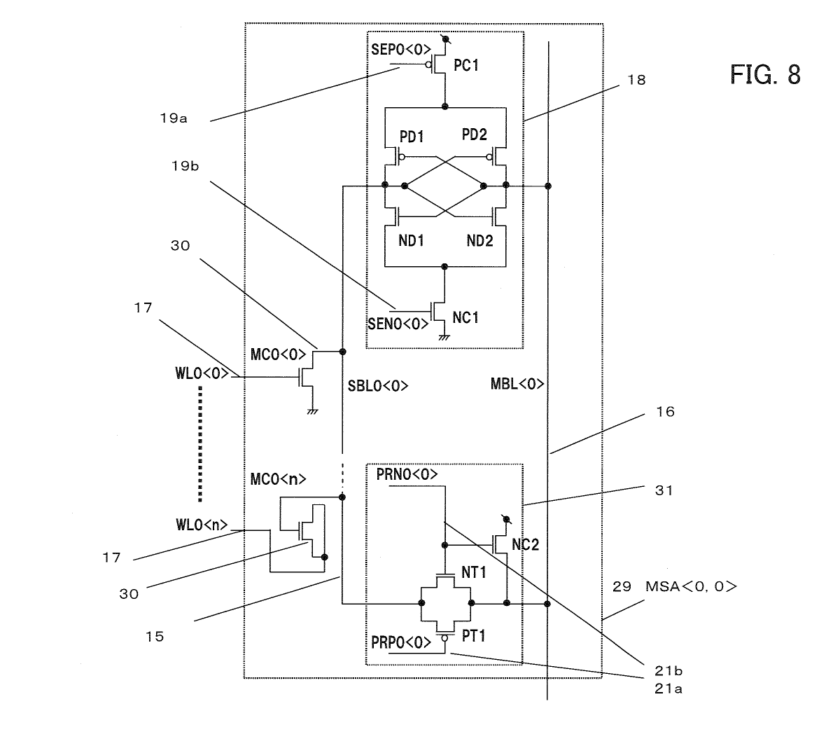

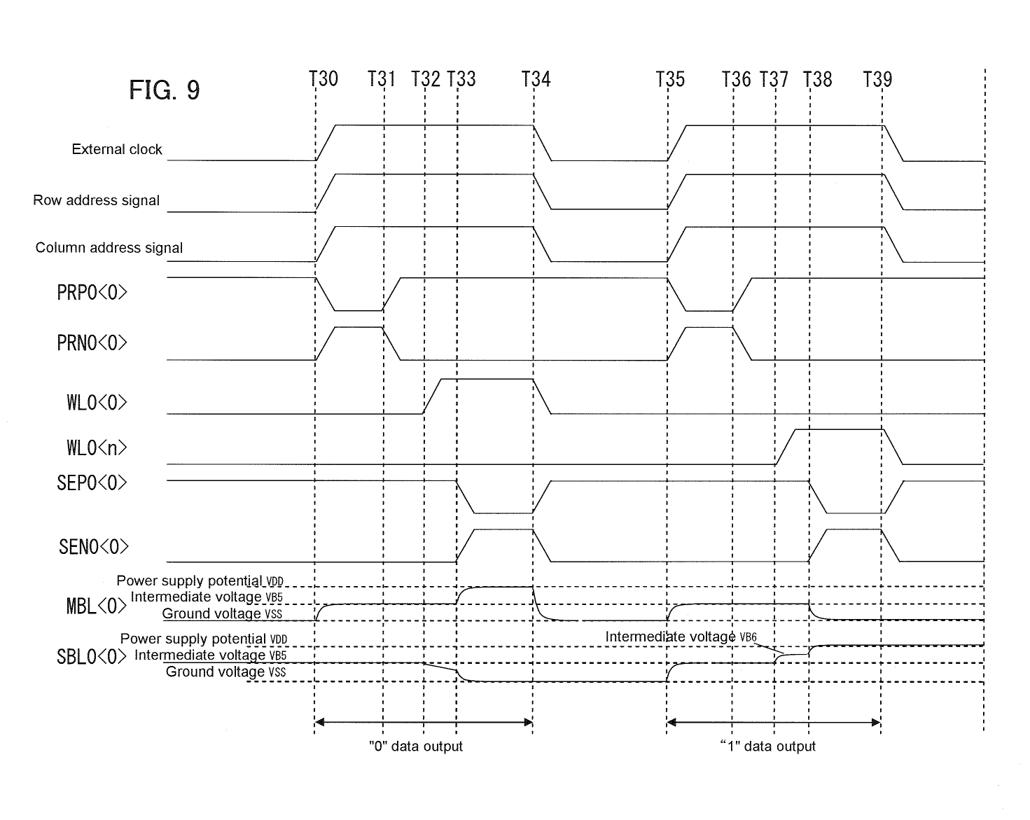

Next, the operation of FIG. 7 will be described referring to FIGS. 8 and 9. FIG. 8 is a schematic view showing the sub-array according to the third embodiment of the present invention and is different from FIG. 2 only in that the memory cell group 14 is replaced with a memory cell group 30 and that the sub-precharge circuit 20 is replaced with a sub-precharge circuit 31.

The sub-precharge circuit 31 comprises a P-channel MOS transistor PT1 inserted between the sub-bit line 15 SBL0<0> and the main bit line 16 MBL<0>, the gate electrode of which is connected to the sub-precharge control signal 21a PRP0<0>; an N-channel MOS transistor NT1 inserted between the sub-bit line 15 SBL0<0> and the main bit line 16 MBL<0>, the gate electrode of which is connected to the sub-precharge control signal 21b PRN0<0>; and an N-channel MOS transistor NC2 inserted between the main bit line 16 MBL<0> and the power supply voltage Vdd, the gate electrode of which is connected to the sub-precharge control signal 21b PRN0<0>.

In the memory cell group 30 MC0<i> (i=1 to n), the word line group 17 WL0<i> (i=1 to n) is connected to the gate electrodes, the source electrodes are connected to the ground voltage Vss, and the drain electrodes are connected to the sub-bit line 15 SBL0<0> (=“0” data is stored); or the gate electrodes are connected to the sub-bit line 15 SBL0<0>, and the source and drain electrodes short-circuited with each other are connected to the word line group WL0<i>(=“1” data is stored). Data to be stored is programmed in a semiconductor manufacturing process.

In the semiconductor memory device configured as described above, its operation will be described using the timing operation waveforms (T30 to T39) shown in FIG. 9. The period from time T30 to time T34 is a “0” data reading period, and the period from time T35 to time T39 is a “1” data reading period.

The period before time T30 and the period from time T34 to time T35: initial state

All the row address signals and column address signals are inactive. Hence, the voltages of the word lines 17 WL0<L> and WL0<n> are “L” level, and the voltage of the main bit line MBL0 is “L” level. The main bit line group 3 MBL<j> being unselected is precharged to “L” level using the main bit line precharge circuit 13. Since the sub-precharge control signal 21a PRP0<0> is “H” level and the sub-precharge control signal 21b PRN0<0> is “L” level at this time, the P-channel MOS transistor PT1, the N-channel MOS transistor NT1 and the N-channel MOS transistor NC2 are nonconductive, and the sub-bit line 15 SBL0<0> becomes a high-impedance (Hi-Z) state. However, since the sub-amp control signal 19a SEP0<0> is “H” level and the sub-amp control signal 19b SEN0<0> is “L” level, the sub-amp circuit 18 is in a stopped state, and no operation trouble occurs.

The period from time T30 to time T31 and the period from time T35 to time T36: main bit line precharging and sub-bit line equalizing periods

One of the row address signals and one of the column address signals are activated, and the main bit line 16 MBL<0> is selected. At this time, the “L” level charging to the main bit line 16 MBL<0> using the main bit line precharge circuit 13 is stopped. The sub-precharge control signal 21a PRP0<0> is a one-shot pulse signal changing from “H”→“L”→“H” level, and the sub-precharge control signal 21b PRN0<0> is a one-shot pulse signal changing from “L”→“H”→“L” level. In this period, since the sub-precharge control signal 21a PRP0<0> is “L” level and the sub-precharge control signal 21b PRN0<0> is “H” level, the P-channel MOS transistor PT1, the N-channel MOS transistor NT1 and the N-channel MOS transistor NC2 become conductive. Hence, the voltages of the sub-bit line 15 SBL0<0> and the main bit line 16 MBL<0> have a value (=the power supply voltage Vdd—the threshold voltage of the N-channel MOS transistor NC2 or less) arbitrarily determined by the cutoff currents generated in the memory cell group 30 MC0<i> connected to the sub-bit line 15 SBL0<0> and the current of the N-channel MOS transistor NC2. This voltage is shown as an intermediate voltage VB5 in FIG. 3.

Time T32: word line selection (“0” data reading start)

When the word line 17 WL0<0> is activated at time T32, the voltage of the sub-bit line 15 SBL0<0> is gradually lowered to the ground voltage Vss via the memory cell 30 MC0<0>.

Time T33: sub-amp start (“0” data reading completion)

At time T33, the sub-amp control signal 19a SEP0<0> becomes “L” level, the sub-amp control signal 19b SEN0<0> becomes “H” level, and the sub-amp circuit 18 is started. The sub-amp circuit 18 recognizes that the voltage of the sub-bit line 15 SBL0<0> is “L” level and lowers the voltage to the ground voltage Vss, and recognizes that the voltage of the main bit line 16 MBL<0> is “H” level and raises the voltage to the power supply voltage Vdd by adjusting time T33 so that the voltage of the sub-bit line 15 SBL0<0> becomes sufficiently lower than the voltage VB1 of the main bit line 16 MBL<0>.

The “H” level voltage of the main bit line 16 MBL<0> is output as “0” data to the outside of the mask ROM via the main amp 8 and the data output buffer 9.

Time T37: word line selection (“1” data reading start)

When the word line 17 WL0<n> is activated at time T37, charge redistribution occurs between the gate capacity of the memory cell 30 MC0<n> and the capacity of the sub-bit line, and the voltage of the sub-bit line 15 SBL0<0> is raised to an arbitrary level. This voltage is shown as VB6 in FIG. 9.

Time T38: sub-amp start (“1” data reading completion)

At time T38, the sub-amp control signal 19a SEP0<0> is activated to “L” level and the sub-amp control signal 19b SEN0<0> is activated to “H” level, and the sub-amp circuit 18 is started. Since the voltage VB5 of the main bit line 16 MBL<0> is sufficiently lower than the voltage VB6 of the sub-bit line 15 SBL0<0>, the sub-amp circuit 18 recognizes that the voltage of the main bit line 16 MBL<0> is “L” level and lowers the voltage to the ground voltage Vss.

The “L” level voltage of the main bit line 16 MBL<0> is output as “1” data to the outside of the mask ROM via the main amp 8 and the data output buffer 9.

Time T34, time T39; end of reading operation

Since the row address signal and the column address signal are inactivated respectively, the “L” level charging to the main bit line 16 MBL<0> is restarted using the main bit line precharge circuit 13.

The semiconductor memory device according to the third embodiment of the present invention is large in memory cell size in comparison with the first embodiment of the present invention as described above; however, since additional charging to the sub-bit lines is not necessary, current consumption can be reduced, and a mask ROM having larger memory capacity and being capable of reading data at high speed can be created.

### Fourth Embodiment

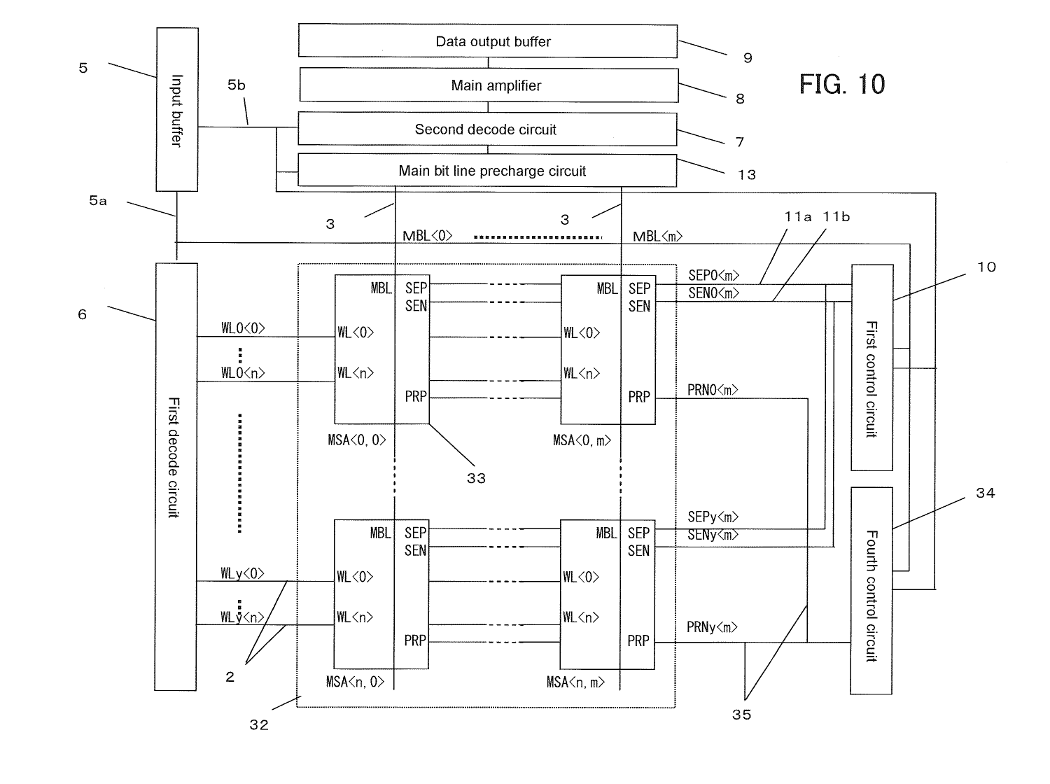

FIG. 10 is a schematic view showing a circuit according to a fourth embodiment of the present invention.

Since FIG. 10 is different from FIG. 1 showing the first embodiment of the present invention only in that the memory cell array 1 is replaced with a memory cell array 32, that the sub-array 4 is replaced with a sub-array 33, that the second control circuit 11 is replaced with a fourth control circuit 34, and that the sub-precharge control signals 12a and 12b are replaced with a sub-precharge control signal 35, its detailed description is omitted.

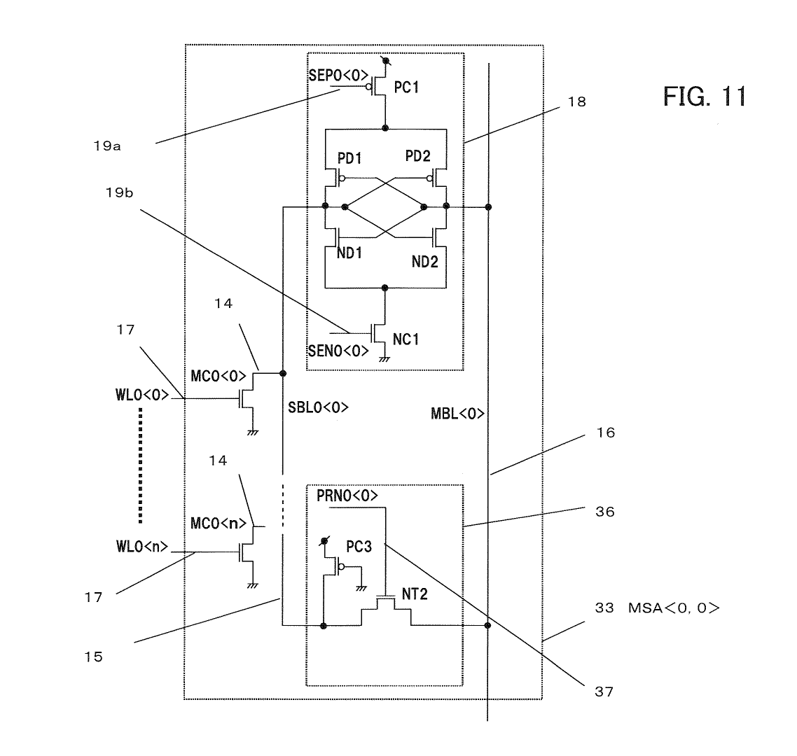

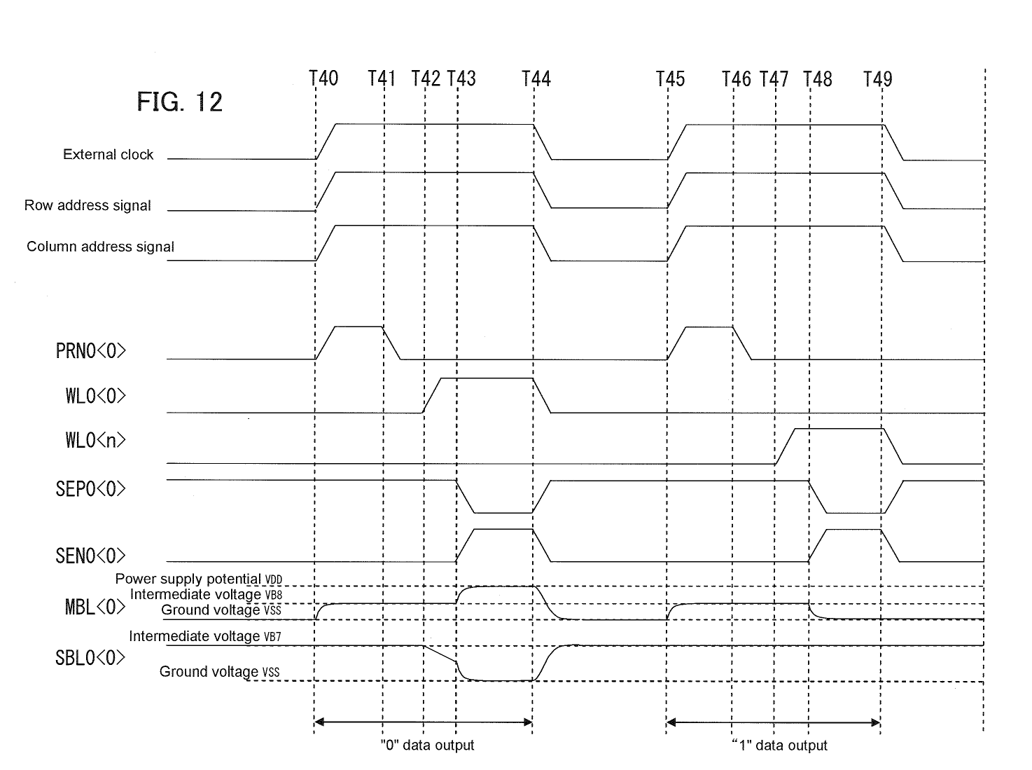

Next, the operation of FIG. 10 will be described referring to FIGS. 11 and 12. FIG. 11 is a schematic view showing the sub-array according to the fourth embodiment of the present invention and is different from FIG. 2 only in that the sub-precharge circuit 20 is replaced with a sub-precharge circuit 36 and that the sub-precharge control signals 21a and 21b are replaced with a sub-precharge control signal 37.

The sub-precharge circuit 36 comprises an N-channel MOS transistor NT2 inserted between the sub-bit line 15 SBL0<0> and the main bit line 16 MBL<0>, the gate electrode of which is connected to the sub-precharge control signal 37 PRN0<0>; and a P-channel MOS transistor PC3 inserted between the sub-bit line 15 SBL0<0> and the power supply voltage Vdd, the gate electrode of which is grounded.

In the semiconductor memory device configured as described above, its operation will be described using the timing operation waveforms (T40 to T49) shown in FIG. 12. The period from time T40 to time T44 is a “0” data reading period, and the period from time T45 to time T49 is a “1” data reading period.

The period before time T40 and the period from time T44 to time T45: initial state

All the row address signals and column address signals are inactive. Hence, the voltages of the word lines 17 WL0<L> and WL0<n> are “L” level, and the voltage of the main bit line MBL<0> is “L” level. The main bit line group 3 MBL<j> being unselected is precharged to “L” level using the main bit line precharge circuit 13. Since the sub-precharge control signal 37 PRN0<0> is “L” level at this time, the N-channel MOS transistor NT2 is nonconductive, and the P-channel MOS transistor PC3 is conductive at all times. Hence, the voltage of the sub-bit line 15 SBL0<0> is arbitrarily determined by the current capability of the P-channel MOS transistor PC3 and the cutoff currents generated in the memory cell group 14 MC0<i> connected to the sub-bit line 15 SBL0<0>. This voltage is shown as an intermediate voltage VB7 in FIG. 12.

The period from time T40 to time T41 and the period from time T45 to time T46: main bit line precharging and sub-bit line equalizing periods

One of the row address signals and one of the column address signals are activated, and the main bit line 16 MBL<0> is selected. At this time, the “L” level charging to the main bit line 16 MBL<0> using the main bit line precharge circuit 13 is stopped. The sub-precharge control signal 34 PRN0<0> is a one-shot pulse signal changing from “L”→“H”→“L” level; in this period, since the signal is “H” level, the N-channel MOS transistor NT2 become conductive. Hence, the voltage of the sub-bit line 15 SBL0<0> is maintained at the intermediate voltage VB7. Since the main bit line 16 MBL<0> is short-circuited with the sub-bit line 15 SBL0<0> via the N-channel MOS transistor NT2, the voltage of the main bit line becomes the intermediate voltage VB7—the threshold voltage of the N-channel MOS transistor NT2 (shown as an intermediate voltage VB8 in FIG. 12).

Time T42: word line selection (“0” data reading start)

When the word line 17 WL0<0> is activated at time T42, the voltage of the sub-bit line 15 SBL0<0> is gradually lowered to the ground voltage Vss via the memory cell 14 MC0<0>.

Time T43: sub-amp start (“0” data reading completion)

At time T43, the sub-amp control signal 19a SEP0<0> becomes “L” level, the sub-amp control signal 19b SEN0<0> becomes “H” level, and the sub-amp circuit 18 is started. The sub-amp circuit 18 recognizes that the voltage of the sub-bit line 15 SBL0<0> is “L” level and lowers the voltage to the ground voltage Vss, and recognizes that the voltage of the main bit line 16 MBL<0> is “H” level and raises the voltage to the power supply voltage Vdd by adjusting time T43 so that the voltage of the sub-bit line 15 SBL0<0> becomes sufficiently lower than the voltage VB7 of the main bit line 16 MBL<0>.

The “H” level voltage of the main bit line 16 MBL<0> is output as “0” data to the outside of the mask ROM via the main amp 8 and the data output buffer 9.

Time T47: word line selection (“1” data reading start)

Even when the word line 17 WL0<n> is activated at time T47, the voltage of the sub-bit line 15 SBL0<0> is maintained at the intermediate voltage VB7.

Time T48: sub-amp start (“1” data reading completion)

At time T48, the sub-amp control signal 19a SEP0<0> is activated to “L” level and the sub-amp control signal 19b SEN0<0> is activated to “H” level, and the sub-amp circuit 18 is started. Since the voltage VB8 of the main bit line 16 MBL<0> is lower than the voltage VB7 of the sub-bit line 15 SBL0<0> by the threshold voltage of the N-channel MOS transistor NT2, the sub-amp circuit 18 recognizes that the voltage of the main bit line 16 MBL<0> is “L” level and lowers the voltage to the ground voltage Vss.

The “L” level voltage of the main bit line 16 MBL<0> is output as “1” data to the outside of the mask ROM via the main amp 8 and the data output buffer 9.

Time T44, time T49; end of reading operation

Since the row address signal and the column address signal are inactivated respectively, the “L” level charging to the main bit line 16 MBL<0> is restarted using the main bit line precharge circuit 13. Furthermore, since the sub-amp control signal 19a SEP0<0> and the sub-amp control signal 19b SEN0<0> are inactivated respectively, the sub-bit line 15 SBL0<0> is charged to the intermediate voltage VB7.

The semiconductor memory device according to the fourth embodiment of the present invention is reduced in the number of elements by two and in the number of signals by one in comparison with the first embodiment of the present invention as described above, whereby the area is made smaller, and a mask ROM having larger memory capacity and being capable of reading data at high speed can be created.

### Fifth Embodiment

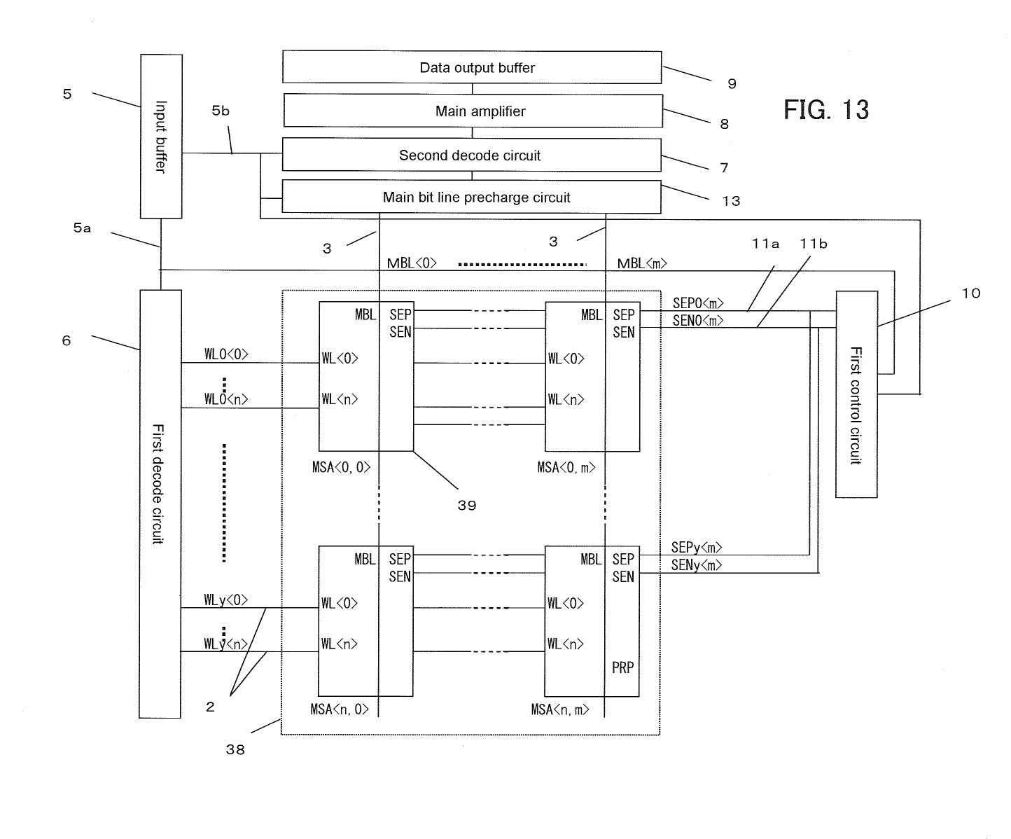

FIG. 13 is a schematic view showing a circuit according to a fifth embodiment of the present invention.

Since FIG. 13 is different from FIG. 1 showing the first embodiment of the present invention only in that the memory cell array 1 is replaced with a memory cell array 38, that the sub-array 4 is replaced with a sub-array 39, and that the second control circuit 11, the sub-precharge control signals 12a PRPk<i> and 12b PRNk<i> are eliminated, its detailed description is omitted.

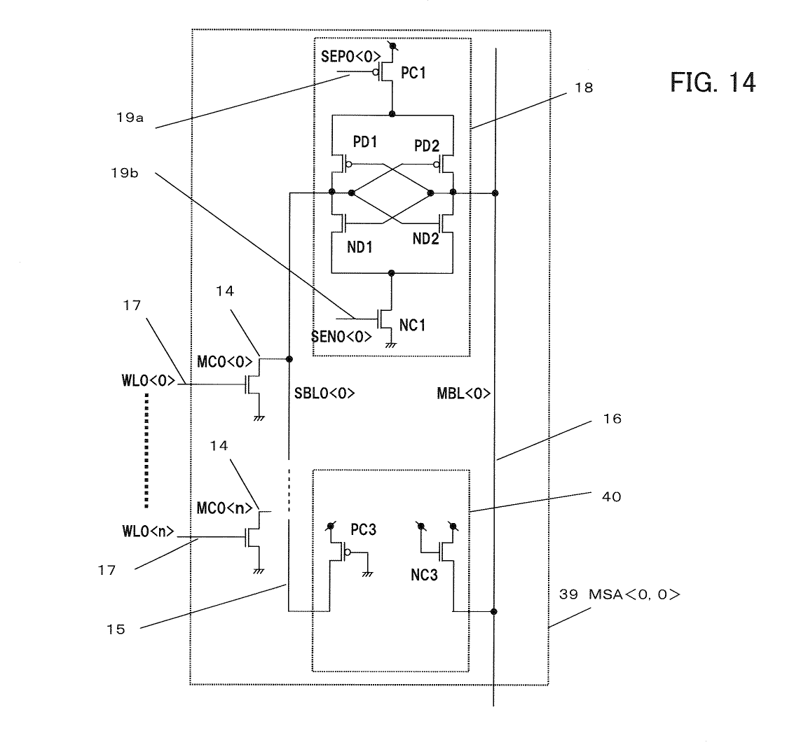

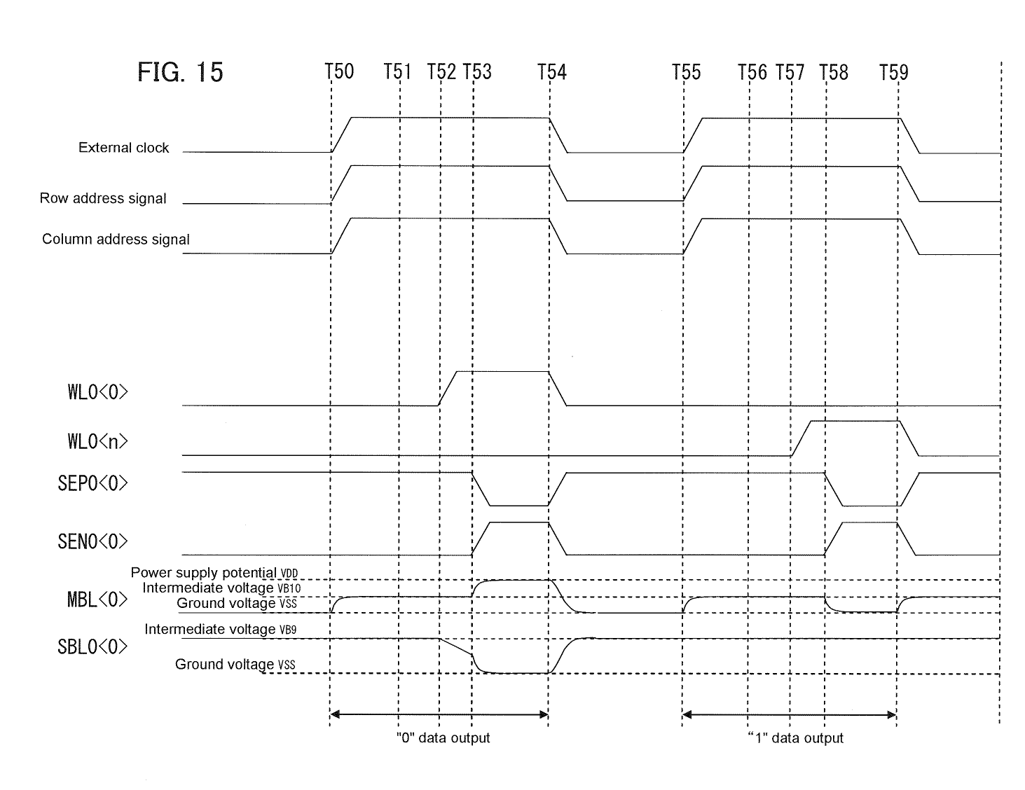

Next, the operation of FIG. 13 will be described referring to FIGS. 14 and 15. FIG. 14 is a schematic view showing the sub-array according to the fifth embodiment of the present invention and is different from FIG. 2 only in that the sub-precharge circuit 20 is replaced with a sub-precharge circuit 40 and that the sub-precharge control signals 21a PRP0<0> and 21b PRN0<0> are eliminated.

The sub-precharge circuit 40 comprises a P-channel MOS transistor PC3 inserted between the sub-bit line 15 SBL0<0> and the power supply voltage Vdd, the gate electrode of which is connected to the ground voltage Vss, and an N-channel MOS transistor NC3 inserted between the main bit line 16 SBL0<0> and the power supply voltage Vdd, the gate electrode of which is connected to the power supply voltage Vdd.

In the semiconductor memory device configured as described above, its operation will be described using the timing operation waveforms (T50 to T59) shown in FIG. 15. The period from time T50 to time T54 is a “0” data reading period, and the period from time T55 to time T59 is a “1” data reading period.

The period before time T50 and the period from time T54 to time T55: initial state

All the row address signals and column address signals are inactive. Hence, the voltages of the word lines 17 WL0<1> and WL0<n> are “L” level. The voltage of the sub-bit line 15 SBL0<0> is arbitrarily determined by the current capability of the P-channel MOS transistor PC3 and the cutoff currents generated in the memory cell group 14 MC0<i>(this voltage is shown as an intermediate voltage VB9 in FIG. 15), and the voltage of the main bit line MBL<0> becomes “L” level. The main bit line group 3 MBL<j> being unselected is precharged to “L” level using the main bit line precharge circuit 13.

The period from time T50 to time T51 and the period from time T55 to time T56: main bit line precharging period

One of the row address signals and one of the column address signals are activated, and the main bit line 16 MBL<0> is selected, and the “L” level charging to the main bit line 16 MBL<0> using the main bit line precharge circuit 13 is stopped. Hence, charging to “H” level is carried out using the N-channel MOS transistor NC3. This voltage is shown as an intermediate voltage VB10 in FIG. 15.

Time T52: word line selection (“0” data reading start)

When the word line 17 WL0<0> is activated at time T52, the voltage of the sub-bit line 15 SBL0<0> is gradually lowered to the ground voltage Vss via the memory cell 14 MC0< >.

Time T53: sub-amp start (“0” data reading completion)

At time T53, the sub-amp control signal 19a SEP0<0> becomes “L” level, the sub-amp control signal 19b SEN0<0> becomes “H” level, and the sub-amp circuit 18 is started. The sub-amp circuit 18 recognizes that the voltage of the sub-bit line 15 SBL0<0> is “L” level and lowers the voltage to the ground voltage Vss, and recognizes that the voltage of the main bit line 16 MBL<0> is “H” level and raises the voltage to the power supply voltage Vdd by adjusting time T53 so that the voltage of the sub-bit line 15 SBL0<0> becomes sufficiently lower than the voltage VB10 of the main bit line 16 MBL<0>.

The “H” level voltage of the main bit line 16 MBL<0> is output as “0” data to the outside of the mask ROM via the main amp 8 and the data output buffer 9.

Time T57: word line selection (“1” data reading start)

Even when the word line 17 WL0<n> is activated at time T57, the voltage of the sub-bit line 15 SBL0<0> is maintained at the intermediate voltage VB9.

Time T58: sub-amp start (“1” data reading completion)

At time T58, the sub-amp control signal 19a SEP0<0> is activated to “L” level and the sub-amp control signal 19b SEN0<0> is activated to “H” level, and the sub-amp circuit 18 is started. Since the voltage VB10 of the main bit line 16 MBL<0> is lower than the voltage VB9 of the sub-bit line 15 SBL0<0> by the threshold voltage of the N-channel MOS transistor NC3, the sub-amp circuit 18 recognizes that the voltage of the main bit line 16 MBL<0> is “L” level and lowers the voltage to the ground voltage Vss.

The “L” level of the main bit line 16 MBL<0> is output as “1” data to the outside of the mask ROM via the main amp 8 and the data output buffer 9.

Time T54, time T59; end of reading operation

Since the row address signal and the column address signal are inactivated respectively, the “L” level charging to the main bit line 16 MBL<0> is restarted using the main bit line precharge circuit 13. Furthermore, since the sub-amp control signal 19a SEP0<0> and the sub-amp control signal 19b SEN0<0> are inactivated respectively, the sub-bit line 15 SBL0<0> is charged to the intermediate voltage VB9.

It is undeniable that the semiconductor memory device according to the fifth embodiment of the present invention is increased in current, but reduced in the number of elements by two and in the number of signals by two in comparison with the first embodiment of the present invention as described above; hence, the area is made smaller, and a mask ROM having larger memory capacity and being capable of reading data at high speed can be created.

### Sixth Embodiment

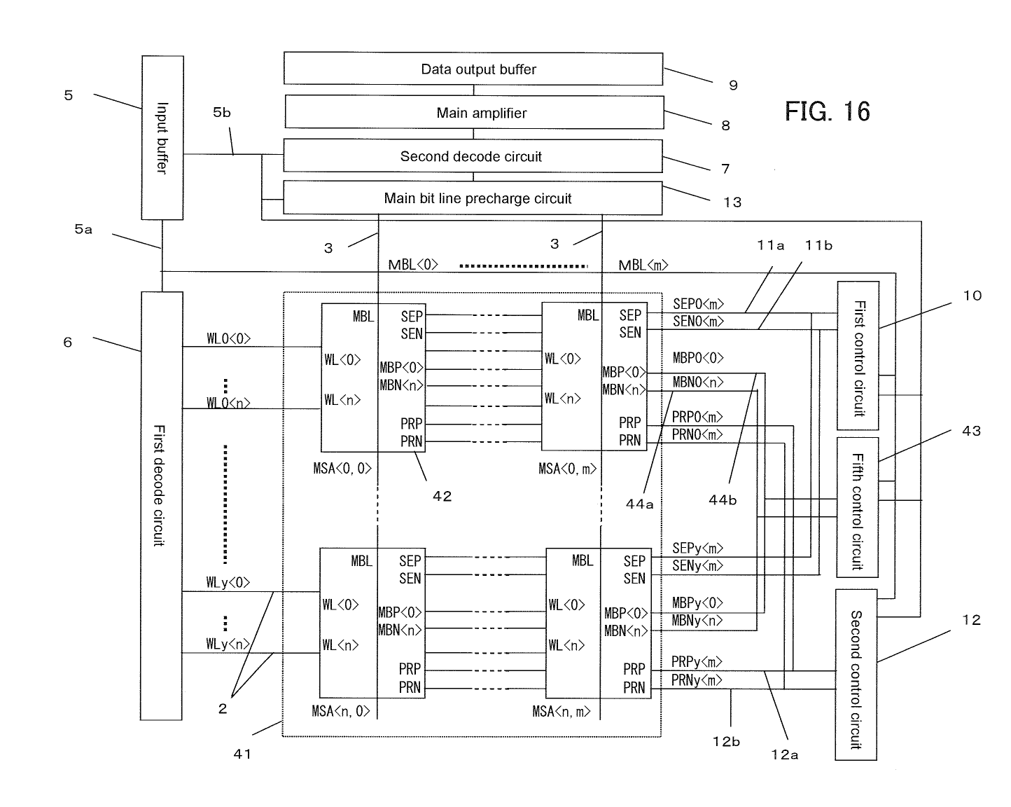

FIG. 16 is a schematic view showing a circuit according to a sixth embodiment of the present invention.

Since FIG. 16 is different from FIG. 1 showing the first embodiment of the present invention in that the memory cell array 1 is replaced with a memory cell array 41, that the sub-array 4 is replaced with a sub-array 42, and that a fifth control circuit 43, main bit line control signals 44a MBPk<j> (k=0 to y, j=0 to m) and main bit line control signal 44b MBNk<j> (k=0 to y, j=0 to m) are added. The fifth control circuit 43 generates the main bit line control signals 44a MBPk<j> and the main bit line control signal 44b MBNk<j> depending on the row address selection signal 5a and the column address selection signal 5b.

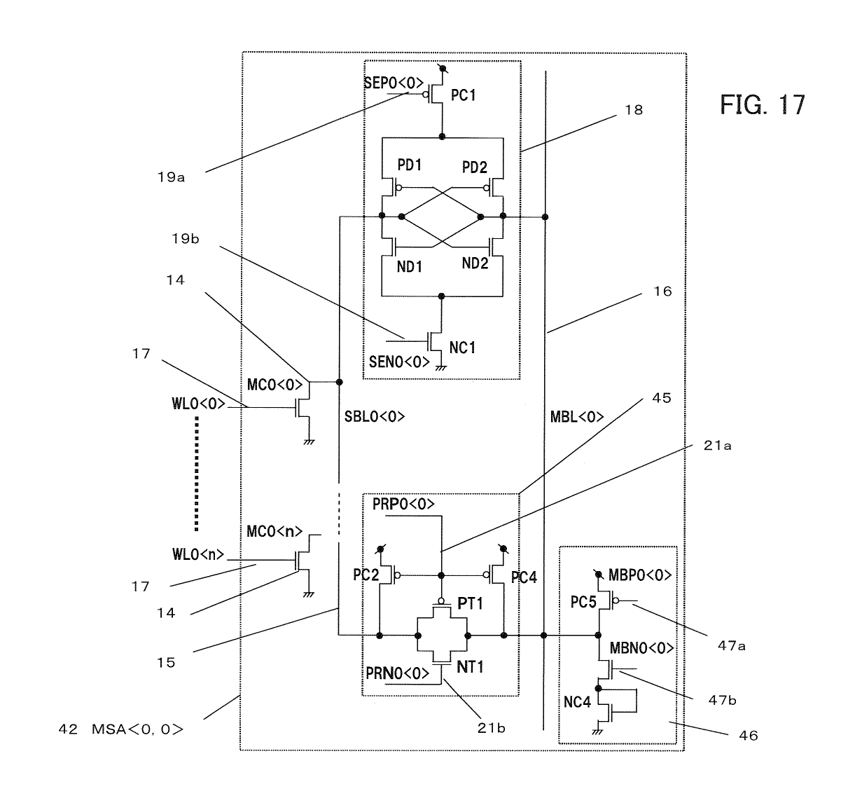

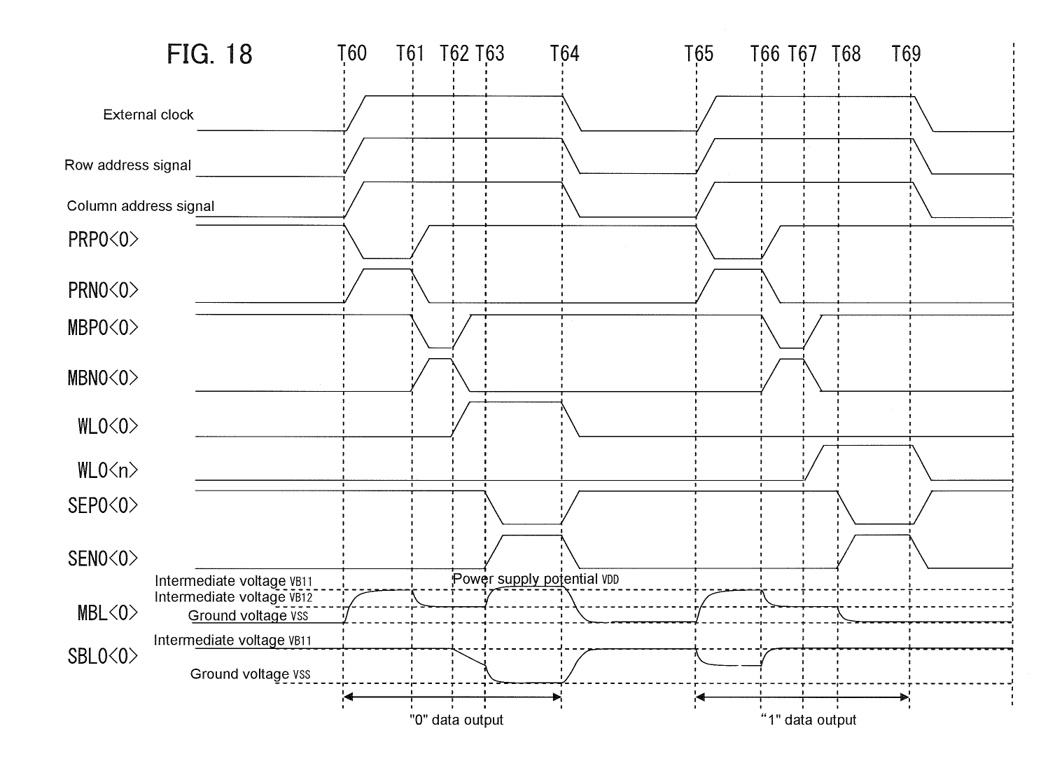

Next, the operation of FIG. 16 will be described referring to FIGS. 17 and 18. FIG. 17 is a schematic view showing the sub-array according to the sixth embodiment of the present invention and is different from FIG. 2 in that the sub-precharge circuit 20 is replaced with a sub-precharge circuit 45 and that a main bit line control circuit 46, a main bit line control signal 47a MBP0<0> and a main bit line control signal 47b MBN0<0> are added.

The sub-precharge circuit 45 comprises a P-channel MOS transistor PT1 inserted between the sub-bit line 15 SBL0<0> and the main bit line 16 MBL<0>, the gate electrode of which is connected to the sub-precharge control signal 21a PRP0<0>; an N-channel MOS transistor NT1 inserted between the sub-bit line 15 SBL0<0> and the main bit line 16 MBL<0>, the gate electrode of which is connected to the sub-precharge control signal 21b PRN0<0>; a P-channel MOS transistor PC2 inserted between the sub-bit line 15 SBL0<0> and the power supply voltage Vdd, the gate electrode of which is connected to the sub-precharge control signal 21b PRN0<0>; and a P-channel MOS transistor PC4 inserted between the main bit line 16 MBL<0> and the power supply voltage Vdd, the gate electrode of which is connected to the sub-precharge control signal 21a PRP0<0>.

The main bit line control circuit 46 comprises a P-channel MOS transistor PC5 inserted between the main bit line 16 MBL<0> and the power supply voltage Vdd, the gate electrode of which is connected to the main bit line control signal 47a MBP0<0>, and an N-channel MOS transistor NC4 inserted between the main bit line 16 MBL<0> and the ground voltage Vss, the gate electrode of which is connected to the main bit line 47b MBN0<0>.

In the semiconductor memory device configured as described above, its operation will be described using the timing operation waveforms (T60 to T69) shown in FIG. 16. The period from time T60 to time T64 is a “0” data reading period, and the period from time T65 to time T69 is a “1” data reading period.

The period before time T60 and the period from time T64 to time T65: initial state

All the row address signals and column address signals are inactive. Hence, the voltages of the word lines 17 WL0<1> and WL0<n> are “L” level, and the voltage of the main bit line MBL<0> is “L” level. The main bit line group 3 MBL<j> being unselected is precharged to “L” level using the main bit line precharge circuit 13. Since the sub-precharge control signal 21a PRP0<0> is “H” level and the sub-precharge control signal 21b PRN0<0> is “L” level at this time, the P-channel MOS transistor PC2 is nonconductive, and the sub-bit line 15 SBL0<0> becomes a high-impedance (Hiz) state; however, the sub-amp circuit 18 is in a stopped state, and no trouble occurs.

The period from time T60 to time T61 and the period from time T65 to time T66: main bit line precharging and sub-bit line equalizing periods

One of the row address signals and one of the column address signals are activated, and the main bit line 16 MBL<0> is selected. At this time, the “L” level charging to the main bit line 16 MBL<0> using the main bit line precharge circuit 13 is stopped. The sub-precharge control signal 21a PRP0<0> is a one-shot pulse signal changing from “H”→“L”→“H” level, and the sub-precharge control signal 21b PRN0<0> is a one-shot pulse signal changing from “L”→“H”→“L” level. In this period, since the sub-precharge control signal 21a PRP0<0> is “L” level and the sub-precharge control signal 21b PRN0<0> is “H” level, the P-channel MOS transistor PT1, the N-channel MOS transistor NT1, the P-channel MOS transistor PC2 and the P-channel MOS transistor PC4 become conductive. Hence, the voltages of the sub-bit line 15 SBL0<0> and the main bit line 16 MBL<0> have a value arbitrarily determined by the cutoff currents generated in the memory cell group 14 MC0<i> connected to the sub-bit line 15 SBL0<0> and the currents of the P-channel MOS transistor NC2 and the P-channel MOS transistor PC4. This voltage is shown as an intermediate voltage VB11 in FIG. 16.

The period from time T61 to time T62 and the period from time T66 to time T67: main bit line additional charging period

At time T61 and time T66, the sub-precharge control signal 21a PRP0<0> and the sub-precharge control signal 21b PRN0<0> are inactivated respectively, and the main bit line control signal 47a MBP0<0> and the main bit line control signal 47b MBN0<0> are activated respectively. The main bit line control signal 47a MBP0<0> is a one-shot pulse signal changing from “H”→“L”→“H”, and the main bit line control signal 47b MBN0<0> is a one-shot pulse signal changing from “L”→“H”→“L”. When the signals are activated as described above, the P-channel MOS transistor PC5 and the N-channel MOS transistor NC4 of the main bit line control circuit become conductive. Hence, the voltage of the main bit line 16 MBL<0> is determined uniquely by the current capability of the P-channel MOS transistor PC5 and the current capability of the N-channel MOS transistor NC4. This voltage is shown as an intermediate voltage VB12 in FIG. 16. The current capabilities of the P-channel MOS transistor PC5 and the N-channel MOS transistor NC4 are adjusted so that the intermediate voltage VB12 becomes lower than the intermediate voltage VB11.

Time T62: word line selection (“0” data reading start)

When the word line 17 WL0<0> is activated at time T62, the voltage of the sub-bit line 15 SBL0<0> is gradually lowered to the ground voltage Vss via the memory cell 14 MC0<0>.

Time T63: sub-amp start (“0” data reading completion)

At time T63, the sub-amp control signal 19a SEP0<0> becomes “L” level, the sub-amp control signal 19b SEN0<0> becomes “H” level, and the sub-amp circuit 18 is started. The sub-amp circuit 18 recognizes that the voltage of the sub-bit line 15 SBL0<0> is “L” level and lowers the voltage to the ground voltage Vss, and recognizes that the voltage of the main bit line 16 MBL<0> is “H” level and raises the voltage to the power supply voltage Vdd by adjusting time T63 so that the voltage of the sub-bit line 15 SBL0<0> becomes sufficiently lower than the voltage VB12 of the main bit line 16 MBL<0>.

The “H” level voltage of the main bit line 16 MBL<0> is output as “0” data to the outside of the mask ROM via the main amp 8 and the data output buffer 9.

Time T67: word line selection (“1” data reading start)

Even when the word line 17 WL0<n> is activated at time T67, the voltage of the sub-bit line 15 SBL0<0> is maintained at the intermediate voltage VB11.

Time T68: sub-amp start (“1” data reading completion)

At time T68, the sub-amp control signal 19a SEP0<0> is activated to “L” level and the sub-amp control signal 19b SEN0<0> is activated to “H” level, and the sub-amp circuit 18 is started. Since the voltage VB12 of the main bit line 16 MBL<0> is adjusted so as to be lower than the voltage VB11 of the sub-bit line 15 SBL0<0>, the sub-amp circuit 18 recognizes that the voltage of the main bit line 16 MBL<0> is “L” level and lowers the voltage to the ground voltage Vss.

The “L” level voltage of the main bit line 16 MBL<0> is output as “1” data to the outside of the mask ROM via the main amp 8 and the data output buffer 9.

Time T64, time T69: end of reading operation

Since the row address signal and the column address signal are inactivated respectively, the “L” level charging to the main bit line 16 MBL<0> is restarted using the main bit line precharge circuit 13.

It is undeniable that the semiconductor memory device according to the sixth embodiment of the present invention is large in area penalty; however, since it is not necessary to set the sub-bit line to “H” level at the time of inactivation, power consumption can be reduced, and a mask ROM having larger memory capacity and being capable of reading data at high speed can be created.

### INDUSTRIAL APPLICABILITY

The semiconductor memory device according to the present invention has a hierarchic bit line structure, is provided with a differential amplifier circuit between a main bit line and a sub-bit line, and employs a method of setting the voltage of the main bit line so as to be lower than the voltage of the sub-bit line, thereby attaining both the stabilization of reading operation and the increase in capacity, and being useful as a circuit technology capable of reading data at high speed even when the memory cell current is reduced.

1. A semiconductor memory device comprising:
a first memory cell array in which first sub-arrays provided with multiple first memory cells; a sub-bit line; a differential amplifier circuit having first, second, third and fourth input terminals; and a first precharge circuit having fifth, sixth, seventh and eighth input terminals are disposed in a matrix state,
multiple word lines connected to said first sub-arrays,
multiple main bit lines connected to said first sub-arrays, and
a second precharge circuit for charging said multiple main bit lines, wherein
said differential amplifier circuit, said first and second input terminals of which are connected to said sub-bit line and one of said multiple main bit lines, respectively, and said third and fourth input terminals of which are connected to first and second control signals, respectively, amplifies the difference between the voltage of said sub-bit line and the voltage of said main bit line when said first and second control signals are activated, and
the first precharge circuit, the fifth and sixth input terminals of which are connected to the sub-bit line and one of the multiple main bit lines, respectively, and the seventh and eighth input terminals of which are connected to third and fourth control signals, charges the sub-bit line and the main bit line to a first voltage when the third and fourth control signals are activated, and charges the sub-bit line to a second voltage when the third and fourth control signals are inactivated.

2. The semiconductor memory device according to claim 1, wherein said first memory cell is formed of an N-channel MOS transistor, the gate electrode of which is connected to one of said multiple word lines, the source electrode of which is connected to a ground voltage Vss, and the drain electrode of which is programmably connected to said sub-bit line according to data to be stored.

3. The semiconductor memory device according to claim 1, wherein said first precharge circuit comprises first and second switching means inserted between said fifth input terminal and said sixth input terminal so as to be connected in parallel with each other, third switching means inserted between a power supply voltage Vdd and said fifth input terminal, and fourth switching means inserted between the power supply voltage Vdd and said sixth input terminal,
said first switching means is formed of an N-channel MOS transistor, the gate electrode of which is connected to said seventh input terminal,
said second switching means is formed of a P-channel MOS transistor, the gate electrode of which is connected to said eighth input terminal,
the third switching means is formed of a P-channel MOS transistor, the gate electrode of which is connected to said seventh input terminal,
the fourth switching means is formed of an N-channel MOS transistor, the gate electrode of which is connected to said seventh input terminal,
when said third control signal connected to said seventh input terminal is activate (“H” level) and said fourth control signal connected to said eighth input terminal is also active (“L” level), said first, second and fourth switching means become conductive, and said third switching means become nonconductive, whereby said sub-bit line connected to said fifth input terminal and said main bit line connected to said sixth input terminal are connected to the power supply voltage Vdd via said fourth switching means, thereby charging said sub-bit line to said first voltage, and
when said third control signal connected to said seventh input terminal is inactivate (“L” level) and said fourth control signal connected to said eighth input terminal is also inactive (“H” level), said first, second and fourth switching means become nonconductive, and said third switching means become conductive, whereby said sub-bit line is connected to the power supply voltage Vdd via said third switching means, thereby charging said sub-bit line to said second voltage.

4. The semiconductor memory device according to claim 1, wherein said first voltage is equal to or lower than “the power supply voltage Vdd—the threshold voltage of said fourth switching means” although said first voltage is determined by the current drive capability of said fourth switching means and the cutoff currents of said multiple first memory cells connected to said sub-bit line.

5. The semiconductor memory device according to claim 1, wherein said second voltage is judged to be H” level in said differential amplifier circuit while said first voltage is used as a reference voltage although said second voltage is determined by the current drive capability of said third switching means and the cutoff currents of said multiple first memory cells connected to said sub-bit line.

6. The semiconductor memory device according to claim 1, wherein
said first and second control signals are activated after said word line is activated,
said third and fourth control signals are pulse signals that are activated in synchronization with an external clock and inactivated after said main bit line and said sub-bit line are charged to said first voltage, and
said word line is activated after said third and fourth control signals are inactivated and after said sub-bit line is charged to said second voltage.

7. The semiconductor memory device according to claim 1, wherein said second precharge circuit charges said main bit line being inactive to “L” level.

8. The semiconductor memory device according to claim 1, wherein said third switching means has a gate width and a gate length so that the current drive capability of said third switching means is smaller than the current drive capability of said first memory cell and larger than the cutoff current of said first memory cell.

9. The semiconductor memory device according to claim 1, wherein said fourth switching means has a gate width and a gate length corresponding to the current drive capability of said fourth switching means so that said second voltage is judged to be “H” level in said differential amplifier circuit while said first voltage is used as a reference voltage.

10. The semiconductor memory device according to claim 1, wherein a number of said first memory cells connected to said sub-bit line is a number so that the total amount of the cutoff currents of said first memory cells connected to said sub-bit line is smaller than the current drive capability of said third switching means.

11. A semiconductor memory device comprising:
a second memory cell array in which second sub-arrays provided with multiple second memory cells; a sub-bit line; a differential amplifier circuit having first, second, third and fourth input terminals; and a first precharge circuit having fifth, sixth, seventh and eighth input terminals are disposed in a matrix state,
multiple word lines connected to said second sub-arrays,
multiple main bit lines connected to said second sub-arrays, and
a second precharge circuit for charging said multiple main bit lines, wherein
said differential amplifier circuit, said first and second input terminals of which are connected to said sub-bit line and one of said multiple main bit lines, respectively, and said third and fourth input terminals of which are connected to first and second control signals, respectively, amplifies the difference between the voltage of said sub-bit line and the voltage of said main bit line when said first and second control signals are activated,
said first precharge circuit, said fifth and sixth input terminals of which are connected to said sub-bit line and one of said multiple main bit lines, respectively, and said seventh and eighth input terminals of which are connected to third and fourth control signals, charges said sub-bit line and said main bit line to a third voltage when said third and fourth control signals are activated, and charges only said sub-bit line to a fourth voltage when said third and fourth control signals are inactivated.

12. The semiconductor memory device according to claim 11, wherein said second memory cell is formed of an N-channel MOS transistor, the gate electrode of which is connected to one of said multiple word lines, the source electrode of which is connected to a fifth control signal group, and the drain electrode of which is programmably connected to said sub-bit line according to data to be stored.

13. The semiconductor memory device according to claim 12, wherein said fifth control signal becomes active (=ground voltage Vss) when one cell of said second memory cell group is accessed by the source electrodes of said second memory cell group disposed in the same row as one of said multiple word lines, and becomes inactive (=fifth voltage) when no cells of said second memory cell group are accessed, whereby that said fifth voltage raises the threshold voltage of said second memory cell and suppresses the generation of cutoff current.

14. The semiconductor memory device according to claim 11, wherein
said first precharge circuit comprises first and second switching means inserted between said fifth input terminal and said sixth input terminal so as to be connected in parallel with each other, third switching means inserted between a power supply voltage Vdd and said fifth input terminal, and fourth switching means inserted between the power supply voltage Vdd and said sixth input terminal,
said first switching means is formed of an N-channel MOS transistor, the gate electrode of which is connected to said seventh input terminal,
said second switching means is formed of a P-channel MOS transistor, the gate electrode of which is connected to said eighth input terminal,
said third switching means is formed of a P-channel MOS transistor, the gate electrode of which is connected to said seventh input terminal,
said fourth switching means is formed of an N-channel MOS transistor, the gate electrode of which is connected to said seventh input terminal,
when said third control signal connected to said seventh input terminal is activate (“H” level) and said fourth control signal connected to said eighth input terminal is also active (“L” level), said first, second and fourth switching means become conductive, and said third switching means becomes nonconductive, whereby said sub-bit line connected to said fifth input terminal and said main bit line connected to said sixth input terminal are connected to the power supply voltage Vdd via said fourth switching means, thereby charging said sub-bit line to said third voltage, and
when said third control signal connected to said seventh input terminal is inactivate (“L” level) and said fourth control signal connected to said eighth input terminal is also inactive (“H” level), said first, second and fourth switching means become nonconductive, and said third switching means becomes conductive, whereby said sub-bit line is connected to the power supply voltage Vdd via said third switching means, thereby charging said sub-bit line to said fourth voltage.

15. The semiconductor memory device according to claim 14, wherein
said third voltage is determined by the current drive capability of said fourth switching means and the total amount of the cutoff currents of said multiple second memory cells connected to said sub-bit line but not selected by said word lines,
said fourth voltage is determined by the current drive capability of said third switching means and the total amount of the cutoff currents of said multiple second memory cells connected to said sub-bit line but not selected by said word lines, and
said third voltage is lower than said fourth voltage by the threshold voltage of said fourth switching means, and said fourth voltage is judged to be “H” level in said differential amplifier circuit while said third voltage is used as a reference voltage.

16. A semiconductor memory device comprising:
a third memory cell array in which third sub-arrays provided with multiple third memory cells; a sub-bit line; a differential amplifier circuit having first, second, third and fourth input terminals; and a third precharge circuit having ninth, tenth, 11th and 12th input terminals are disposed in a matrix state,
multiple word lines connected to said third sub-arrays,
multiple main bit lines connected to said third sub-arrays, and
a second precharge circuit for charging said multiple main bit lines, wherein
said differential amplifier circuit, said first and second input terminals of which are connected to said sub-bit line and one of said multiple main bit lines, respectively, and said third and fourth input terminals of which are connected to first and second control signals, respectively, amplifies the difference between the voltage of said sub-bit line and the voltage of said main bit line when said first and second control signals are activated, and
said third precharge circuit, said ninth and tenth input terminals of which are connected to said sub-bit line and one of said multiple main bit lines, respectively, and said 11th and 12th input terminals of which are connected to third and fourth control signals, charges said sub-bit line and said main bit line to a sixth voltage when said third and fourth control signals are activated.

17. The semiconductor memory device according to claim 16, wherein said third memory cell is formed of an N-channel MOS transistor, the gate electrode of which is connected to one of said multiple word lines, the source electrode of which is connected to a ground voltage Vss, and the drain electrode of which is connected to said sub-bit line; or the gate electrode of which is connected to said sub-bit line, and the source electrode and the drain electrode of which are connected to the same one of said multiple word lines.

18. The semiconductor memory device according to claim 16, wherein
said third precharge circuit comprises first and second switching means inserted between said ninth input terminal and said tenth input terminal so as to be connected in parallel with each other, and fifth switching means inserted between a power supply voltage Vdd and said tenth input terminal,
said first switching means is formed of an N-channel MOS transistor, the gate electrode of which is connected to said 11th input terminal,
said second switching means is formed of a P-channel MOS transistor, the gate electrode of which is connected to said 12th input terminal,
said fifth switching means is formed of an N-channel MOS transistor, the gate electrode of which is connected to said 11th input terminal,
when said third control signal connected to said 11th input terminal is activate (“H” level) and said fourth control signal connected to said 12th input terminal is also active (“L” level), said first, second and fifth switching means become conductive,
the charge transferred from the power supply voltage Vdd via said fifth switching means is redistributed between the capacity of said main bit line connected to said tenth input terminal and the capacity of said sub-bit line connected to said ninth input terminal, thereby charging said sub-bit line and said main bit line to said sixth voltage, and
when said third control signal connected to said 11th input terminal is inactivate (“L” level) and said fourth control signal connected to said 12th input terminal is also inactive (“H” level), said first and second switching means become nonconductive, whereby said sub-bit line is electrically disconnected from said main bit line.

19. The semiconductor memory device according to claim 16, wherein
when the gate electrode is connected to said sub-bit line according to stored data and when said word line is connected by short-circuiting the source electrode and the drain electrode in said third memory cell, the voltage of said sub-bit line is raised to a seventh voltage by the redistribution of the charge between the gate capacity and the capacity of said sub-bit line owing to the activation of said word line, and
said seventh voltage is judged to be H” level in said differential amplifier circuit while said sixth voltage is used as a reference voltage.

20. A semiconductor memory device comprising:
a fourth memory cell array in which fourth sub-arrays provided with multiple first memory cells; a sub-bit line; a differential amplifier circuit having first, second, third and fourth input terminals; and a fourth precharge circuit having 13th, 14th and 15th input terminals are disposed in a matrix state,
multiple word lines connected to said fourth sub-arrays,
multiple main bit lines connected to said fourth sub-arrays, and
a second precharge circuit for charging said multiple main bit lines, wherein
said differential amplifier circuit, said first and second input terminals of which are connected to said sub-bit line and one of said multiple main bit lines, respectively, and said third and fourth input terminals of which are connected to first and second control signals, respectively, amplifies the difference between the voltage of said sub-bit line and the voltage of said main bit line when said first and second control signals are activated, and
said fourth precharge circuit, said 13th and 14th input terminals of which are connected to said sub-bit lines and one of said multiple main bit lines, respectively, and said 15th input terminal of which is connected to a sixth control signal, charges said main bit line to an eighth voltage when said sixth control signal is activated.

21. The semiconductor memory device according to claim 20, wherein said first memory cell is formed of an N-channel MOS transistor, the gate electrode of which is connected to one of said multiple word lines, the source electrode of which is connected to a ground voltage Vss, and the drain electrode of which is programmably connected to said sub-bit line according to data to be stored.

22. The semiconductor memory device according to claim 20, wherein
said fourth precharge circuit comprises sixth switching means inserted between said 13th input terminal and said 114th input terminal and seventh switching means inserted between the power supply voltage Vdd and said 13th input terminal,
said sixth switching means is formed of an N-channel MOS transistor, the gate electrode of which is connected to said 15th input terminal,
said seventh switching means is formed of a P-channel MOS transistor, the gate electrode of which is connected to the ground voltage Vss,
when said sixth control signal connected to said 15th input terminal is activate (“H” level), said sixth switching means becomes conductive, and said seventh switching means is conductive at all times, thereby charging the voltage of said main bit line to said eighth voltage, and
said eighth voltage is lower than the voltage of said sub-bit line by the threshold voltage of said sixth switching means, and the voltage of said sub-bit line is judged to be “H” level in said differential amplifier circuit while said eighth voltage is used as a reference voltage.

23. A semiconductor memory device comprising:
a fifth memory cell array in which fifth sub-arrays provided with multiple first memory cells; a sub-bit line; a differential amplifier circuit having first, second, third and fourth input terminals; and a fifth precharge circuit having 16th and 17th input terminals are disposed in a matrix state,
multiple word lines connected to said fifth sub-arrays,
multiple main bit lines connected to said fifth sub-arrays, and
a second precharge circuit for charging said multiple main bit lines, wherein
said differential amplifier circuit, said first and second input terminals of which are connected to said sub-bit line and one of said multiple main bit lines, respectively, and said third and fourth input terminals of which are connected to first and second control signals, respectively, amplifies the difference between the voltage of said sub-bit line and the voltage of said main bit line when said first and second control signals are activated, and
said fifth precharge circuit, said 16th input terminal of which is connected to said sub-bit line, charges said sub-bit line to a ninth voltage, and said fifth precharge circuit, said 17th input terminal of which is connected to said main bit line, charges said main bit line to a tenth voltage.

24. The semiconductor memory device according to claim 23, wherein the first memory cell is formed of an N-channel MOS transistor, the gate electrode of which is connected to one of said multiple word lines, the source electrode of which is connected to a ground voltage Vss, and the drain electrode of which is programmably connected to said sub-bit line according to data to be stored.

25. The semiconductor memory device according to claim 23, wherein
said fifth precharge circuit comprises eighth switching means inserted between said 16th input terminal and a power supply voltage Vdd and ninth switching means inserted between said 17th input terminal and the power supply voltage Vdd,
said eighth switching means is formed of a P-channel MOS transistor, the gate electrode of which is connected to the ground voltage Vss,
said ninth switching means is formed of an N-channel MOS transistor, the gate electrode of which is connected to the power supply voltage Vdd, and
since said eighth switching means is conductive at all times, said sub-bit line is charged to said ninth voltage, and since said ninth switching means is also conductive at all times, said main bit line is charged to said tenth voltage, and said tenth voltage becomes lower than said ninth voltage by at least the threshold voltage of said ninth switching means, and the voltage of said sub-bit line is judged to be “H” level in said differential amplifier circuit while said tenth voltage is used as a reference voltage.

26. A semiconductor memory device comprising:
a sixth memory cell array in which sixth sub-arrays provided with multiple first memory cells; a sub-bit line; a differential amplifier circuit having first, second, third and fourth input terminals; and a sixth precharge circuit having 18th, 19th, 20th and 21st input terminals are disposed in a matrix state,
multiple word lines connected to said sixth sub-arrays,
multiple main bit lines connected to said sixth sub-arrays, and
a seventh precharge circuit having 22nd, 23rd and 24th input terminals, wherein
said differential amplifier circuit, said first and second input terminals of which are connected to said sub-bit line and one of said multiple main bit lines, respectively, and said third and fourth input terminals of which are connected to first and second control signals, respectively, amplifies the difference between the voltage of said sub-bit line and the voltage of said main bit line when said first and second control signals are activated,
said 18th and 19th input terminals of said sixth precharge circuit are connected to said sub-bit line and one of said multiple main bit lines, respectively, and said 20th and 21st input terminals thereof are connected to said third and fourth control signals, respectively,
said 22nd input terminal of said seventh precharge circuit is connected to one of said multiple main bit lines, and said 23rd and 24th input terminal thereof are connected to seventh and eighth control signals, respectively, and
when said third and fourth control signals are activated, said sub-bit line and said main bit line are charged to an 11th voltage; and when said seventh and eighth control signals are activated after said third and fourth control signals are inactivated, only the voltage of said main bit line is charged to a 12th voltage.

27. The semiconductor memory device according to claim 26, wherein said first memory cell is formed of an N-channel MOS transistor, the gate electrode of which is connected to one of said multiple word lines, the source electrode of which is connected to a ground voltage Vss, and the drain electrode of which is programmably connected to said sub-bit line according to data to be stored.

28. The semiconductor memory device according to claim 26, wherein
said sixth precharge circuit comprises tenth and 11th switching means inserted between said 18th input terminal and said 19th input terminal so as to be connected in parallel with each other, 12th switching means inserted between a power supply voltage Vdd and said 18th input terminal, and 13th switching means inserted between the power supply voltage Vdd and said 19th input terminal,
said tenth switching means is formed of an N-channel MOS transistor, the gate electrode of which is connected to said 20th input terminal,
said 11th, 12th and 13th switching means are formed of a P-channel MOS transistor, each gate electrode of which is connected to said 21st input terminal,
said seventh precharge circuit comprises 14th switching means inserted between said 22nd input terminal and the power supply voltage Vdd and 15th switching means inserted between said 22nd input terminal and the ground voltage Vss,
said 14th switching means is formed of a P-channel MOS transistor, the gate electrode of which is connected to said seventh control signal,
said 15th switching means is formed of an N-channel MOS transistor, the gate electrode of which is connected to said eighth control signal,
when said third control signal connected to said 20th input terminal is activate (“H” level), said fourth control signal connected to said 21st input terminal is active (“L” level), said seventh control signal connected to said 23rd input terminal is inactive (“H” level), and said eighth control signal connected to said 24th input terminal is inactive (“L” level), said tenth and 11th switching means become conductive, said 12th and 13th switching means also become conductive, and said 14th and 15th switching means become nonconductive, whereby said sub-bit line and said main bit line are charged to said 11th voltage,
when said third control signal connected to said 20th input terminal is inactivate (“L” level), said fourth control signal connected to said 21st input terminal is inactive (“H” level), said seventh control signal connected to said 23rd input terminal is active (“L” level), and said eighth control signal connected to said 24th input terminal is active (“H” level), said tenth, 11th, 12th and 13th switching means are nonconductive, and said 14th and 15th switching means are conductive, whereby said main bit line is charged to the 12th voltage, and
said 12th voltage is a voltage determined uniquely by the current drive capabilities of said 14th and 15th switching means, and the voltage (=said 11th voltage) of said sub-bit line is judged to be H” level in said differential amplifier circuit while said 12th voltage is used as a reference voltage.
